(19) United States
(12) Patent Application Publication
(10) Pub. No.: US 2024/0387095 A1
(43) Pub. Date: Nov. 21, 2024

(54) POWER CONVERSION DEVICE

(71) Applicant: Mitsubishi Electric Corporation, Tokyo (JP)

(72) Inventor: Kei HAYASE, Tokyo (JP)

(73) Assignee: Mitsubishi Electric Corporation, Tokyo (JP)

(21) Appl. No.: 18/474,475

(22) Filed: Sep. 26, 2023

(30) Foreign Application Priority Data
May 15, 2023 (JP) 2023-079860

(51) Int. Cl. H01F 27/26; H01F 3/14; H01F 27/28; H02M 1/00; H02M 3/335

(52) U.S. Cl. CPC H01F 27/26; H01F 3/14; H01F 27/2828; H02M 1/0064; H02M 3/33573

(57) ABSTRACT

The power conversion device includes: a core; a primary-side coil wound on the core; a secondary-side coil wound on the core; and a smoothing coil wound on the core. The core has a first core, a second core, a center leg which makes connection between a center portion of the first core and a center portion of the second core, and a plurality of side legs which are away from the center leg and each of which makes connection between an end portion of the first core and an end portion of the second core. The primary-side coil and the secondary-side coil are wound on a first side leg among the side legs. The smoothing coil is wound on a second side leg among the side legs. A magnetic path common to the primary-side coil, the secondary-side coil, and the smoothing coil is formed on the center leg.

### BACKGROUND

The present disclosure relates to a power conversion device.

Electric automobiles or hybrid automobiles in various vehicle classes have been developed and prevailing in association with environmental regulations and technological advancement related to automobiles in recent years. A plurality of power conversion devices are mounted on a motorized vehicle in which a motor is used as a drive source as in a hybrid automobile or an electric automobile. Each of the power conversion devices is a device for converting input current from DC into AC and from AC into DC, or converting input voltage into a different voltage. For the power conversion device, a plurality of magnetic parts provided with cores and windings are used. Specific examples of the power conversion device mounted on the motorized vehicle include: a charger that converts commercial AC power into DC power and charges a high-voltage battery with the DC power; a DC/DC converter that converts DC power of a high-voltage battery into DC power having a different voltage; and an inverter that converts DC power from a high-voltage battery into AC power for the motor.

The DC/DC converter is mounted on the motorized vehicle in order to, for example, perform charging from a high-voltage lithium-ion battery to a low-voltage lead battery. The high-voltage lithium-ion battery is insulated from a chassis and a low-voltage grid in order to protect the surroundings from high voltage. In general, the input side with high voltage and the output side with low voltage need to be insulated from each other by an insulation transformer in the DC/DC converter as well. In the DC/DC converter, a semiconductor element or the like is switched to convert DC input voltage into a signal of AC or the like, and the signal is inputted to a primary side of the insulation transformer. The output on a secondary side of the insulation transformer is rectified by a semiconductor element or the like and smoothed by a smoothing reactor. Then, the resultant voltage is outputted as a DC output voltage from the DC/DC converter.

In general, an insulation-type DC/DC converter mounted on an electric automobile or a hybrid automobile is of a kW or higher class. Therefore, an insulation transformer and a smoothing reactor are upsized and easily generate heat. In addition, in an insulation-type DC/DC converter having a plurality of magnetic parts such as the insulation transformer and the smoothing reactor, fixation parts for fixing the respective parts are needed, and thus the number of parts increases. A configuration of a power conversion device having a decreased number of parts has been disclosed (for example, Patent Document 1). In Patent Document 1, a core has a center leg and side legs, windings of a smoothing reactor are wound on the center leg provided with a gap portion, and windings of an insulation transformer are wound on each of the side legs. Since the insulation transformer and the smoothing reactor are integrated with each other, the power conversion device is downsized, and the number of parts in the power conversion device is decreased.
Patent Document 1: Japanese Patent No. 6198994

In particular, a current not smaller than a value that is approximately several hundreds of amperes is necessary in many cases on the secondary side of the DC/DC converter used for the motorized vehicle. Therefore, in general, each of an insulation transformer and a smoothing reactor is designed to be of a planar type in which a flat-plate-shaped winding is used. Employment of the planar type makes it possible to: increase the cross-sectional area of the winding so as to decrease loss; and improve heat dissipation properties so as to suppress increase in the temperature of the coil. However, employment of the planar type leads to increase in the projected area of a winding portion. In a case where the configuration in Patent Document 1 is formed with the planar type, a flat-plate-shaped winding has to be disposed on each of the center leg and the side legs which are adjacent to each other. Consequently, the projected area of the power conversion device in which the insulation transformer and the smoothing reactor have been integrated with each other increases, whereby a problem arises in that the power conversion device is upsized. In addition, the smoothing reactor provided to the center leg is configured to be of a shell type. Thus, there are few exposed portions of the windings of the smoothing reactor, and the windings cannot be sufficiently cooled, whereby a problem arises in that the power conversion device is upsized owing to restrictions of thermal feasibility. In addition, it is necessary to ensure regions in which two flat-plate-shaped windings between the center leg and one of the side legs of the core and two flat-plate-shaped windings between the center leg and the other side leg of the core, i.e., a total of four flat-plate-shaped windings, are arranged. Consequently, the core is upsized, whereby a problem arises in that cost for the power conversion device increases, and the power conversion device is upsized.

In addition, in a case where a primary-side winding of the insulation transformer is connected to a power conversion circuit having semiconductor switching elements, and, in particular, in a case where the power conversion circuit has a circuit configuration employing a hard-switching method in which the ON/OFF duty ratio of a semiconductor switching element on the primary side is changed to adjust output voltage, current having a high frequency flows through the primary-side winding and a secondary-side winding of the insulation transformer owing to vibrations due to resonance of the semiconductor switching element on the primary side and a leakage inductance of the insulation transformer caused when the state of the semiconductor switching element on the primary side is switched from an ON state to an OFF state. Since current having a high frequency flows through the insulation transformer, the heat generation amount of the insulation transformer increases. Thus, each winding is upsized owing to thermal feasibility. Since each winding is upsized, the upsized windings are arranged on the center leg and the side legs so as to be adjacent to each other, whereby a problem arises in that the power conversion device is upsized.

In addition, the core also generates heat owing to the leakage inductance of the insulation transformer and vibrations due to resonance of the semiconductor switching element on the primary side. Since the flat-plate-shaped windings are adjacent to each other, the center leg and the side legs as central axes of the flat-plate-shaped windings are away from each other, and in particular, in a case of a configuration in which only the bottom surface side of the core is thermally connected to a cooler for the purpose of decreasing cost, thermal resistances of cooling paths extending via the center leg and the side legs and located on the top surface side and the bottom surface side of the core increase. Thus, the core is upsized owing to thermal feasibility of the core, whereby a problem arises in that cost for the power conversion device increases, and the power conversion device is upsized.

### SUMMARY

Considering this, an object of the present disclosure is to provide a power conversion device that, while allowing decrease in the number of parts therein, is downsized and requires lower cost.

A power conversion device according to the present disclosure is a power conversion device including: a core forming a magnetic circuit; a primary-side coil wound on the core; a secondary-side coil magnetically coupled to the primary-side coil and wound on the core; and a smoothing coil electrically connected to the secondary-side coil and wound on the core, wherein the core has a first core, a second core opposed to the first core and disposed to be spaced from the first core, a center leg which makes connection between a center portion of the first core and a center portion of the second core opposed to each other, and a plurality of side legs which are away from the center leg and each of which makes connection between an end portion of the first core and an end portion of the second core opposed to each other, the primary-side coil and the secondary-side coil are wound on a first side leg among the side legs, the smoothing coil is wound on a second side leg among the side legs, and a magnetic path common to the primary-side coil, the secondary-side coil, and the smoothing coil is formed on the center leg.

In the power conversion device according to the present disclosure, the core has a first core, a second core opposed to the first core and disposed to be spaced from the first core, a center leg which makes connection between a center portion of the first core and a center portion of the second core opposed to each other, and a plurality of side legs which are away from the center leg and each of which makes connection between an end portion of the first core and an end portion of the second core opposed to each other, the primary-side coil and the secondary-side coil are wound on a first side leg among the side legs, the smoothing coil is wound on a second side leg among the side legs, and a magnetic path common to the primary-side coil, the secondary-side coil, and the smoothing coil is formed on the center leg. Consequently, only the windings of an insulation transformer are present between the center leg and the first side leg, and only the winding of a smoothing reactor is present between the center leg and the second side leg. Therefore, regions for windings that should be ensured between the center leg and the first side leg and between the center leg and the second side leg can be decreased. Since the regions for windings that should be ensured between the center leg and the first side leg and between the center leg and the second side leg are decreased, it is possible to downsize the core and decrease cost therefor while decreasing the number of parts through unification of the insulation transformer and the smoothing reactor. Since the core is downsized and cost therefor is decreased, it is possible to downsize the power conversion device and decrease cost therefor.

### BRIEF DESCRIPTION OF THE DRAWINGS

FIG. 1 shows a circuit configuration of a power conversion device according to a first embodiment;

FIG. 2 shows a configuration of magnetic parts of the power conversion device according to the first embodiment;

FIG. 3 shows operation of a circuit of the power conversion device according to the first embodiment;

FIG. 4 shows magnetic fluxes generated in the magnetic parts of the power conversion device according to the first embodiment;

FIG. 5 shows operation of the circuit of the power conversion device according to the first embodiment;

FIG. 6 shows operation of the circuit of the power conversion device according to the first embodiment;

FIG. 7 shows magnetic fluxes generated in the magnetic parts of the power conversion device according to the first embodiment;

FIG. 8 is an exploded perspective view schematically showing the magnetic parts of the power conversion device according to the first embodiment;

FIGS. 9A and 9B each schematically show the magnetic parts and a cooler of the power conversion device according to the first embodiment;

FIG. 10 shows operation of the circuit of the power conversion device according to the first embodiment;

FIG. 11 shows operation of the circuit of the power conversion device according to the first embodiment;

FIG. 12 shows operation waveforms in the circuit of the power conversion device according to the first embodiment;

FIG. 13 is a plan view schematically showing a main section of a power conversion device according to a second embodiment;

FIGS. 14A and 14B each schematically show a main section of a power conversion device according to a third embodiment;

FIG. 15 schematically shows magnetic parts of a power conversion device according to a fourth embodiment;

FIG. 16 schematically shows a main section of a power conversion device according to a fifth embodiment;

FIG. 17 shows a configuration of magnetic parts of a power conversion device according to a sixth embodiment;

FIG. 18 shows a configuration of other magnetic parts of the power conversion device according to the sixth embodiment; and

FIG. 19 shows a configuration of magnetic parts of a power conversion device according to a seventh embodiment.

### DETAILED DESCRIPTION OF THE EMBODIMENTS

Hereinafter, power conversion devices according to embodiments of the present disclosure will be described with reference to the drawings. Description will be given while the same or corresponding members and portions in the drawings are denoted by the same reference characters.

### First Embodiment

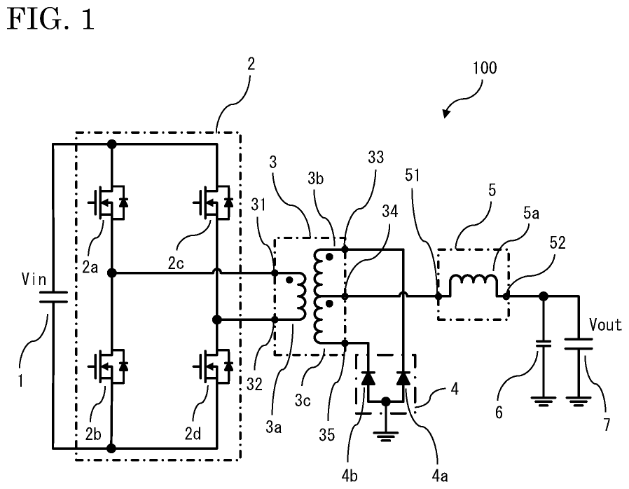

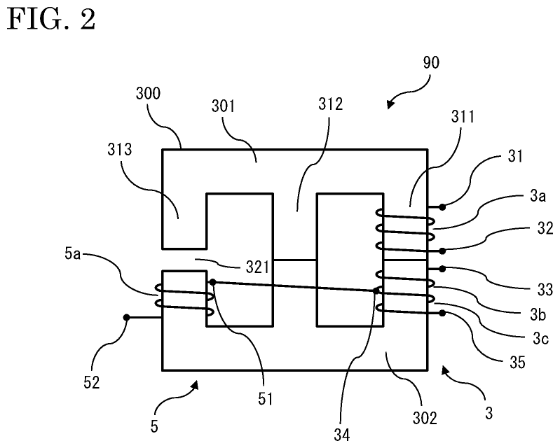

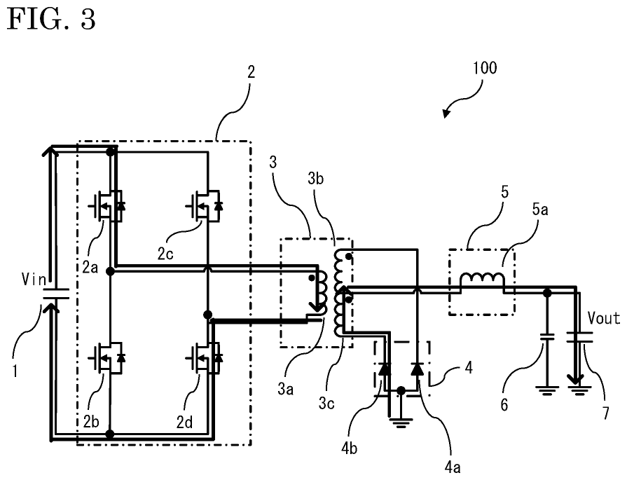

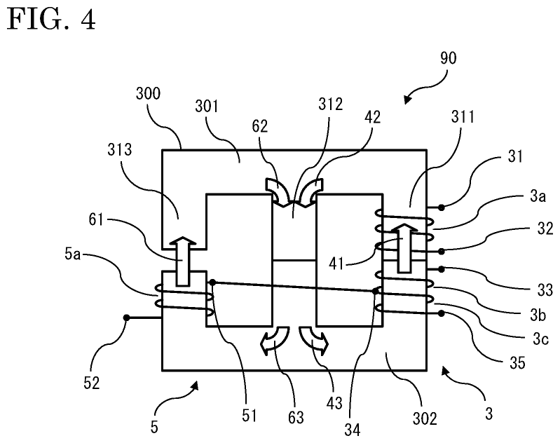

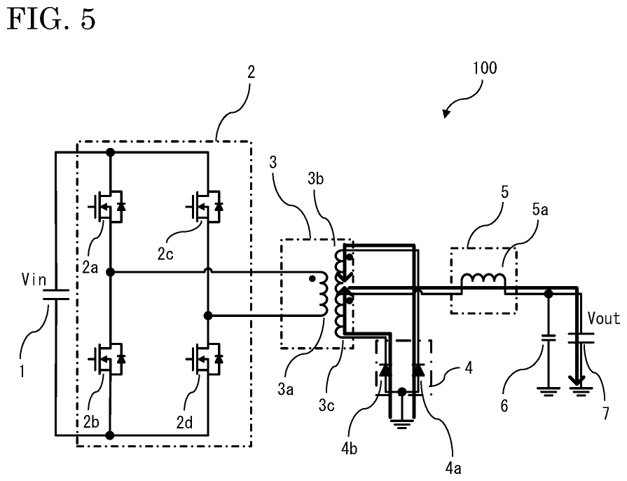

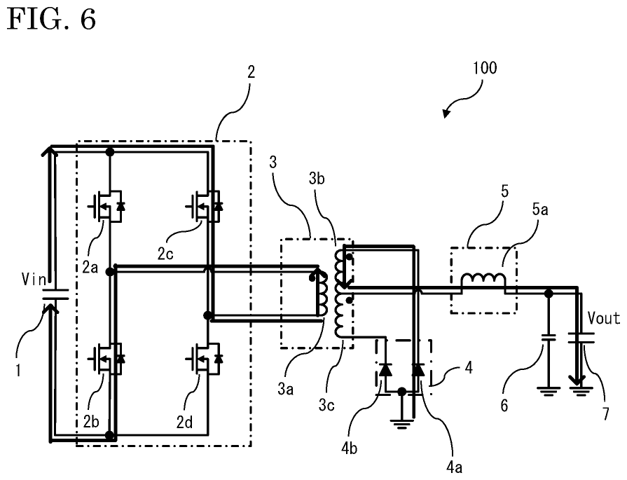

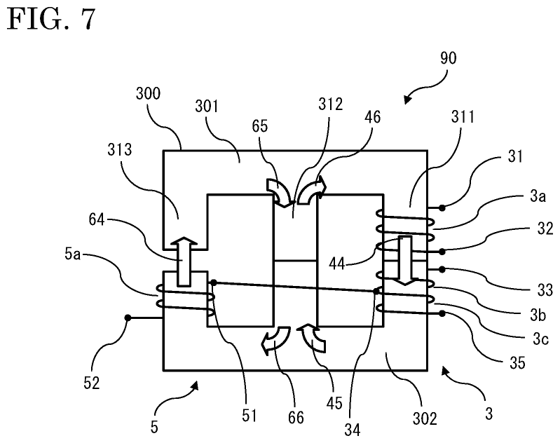

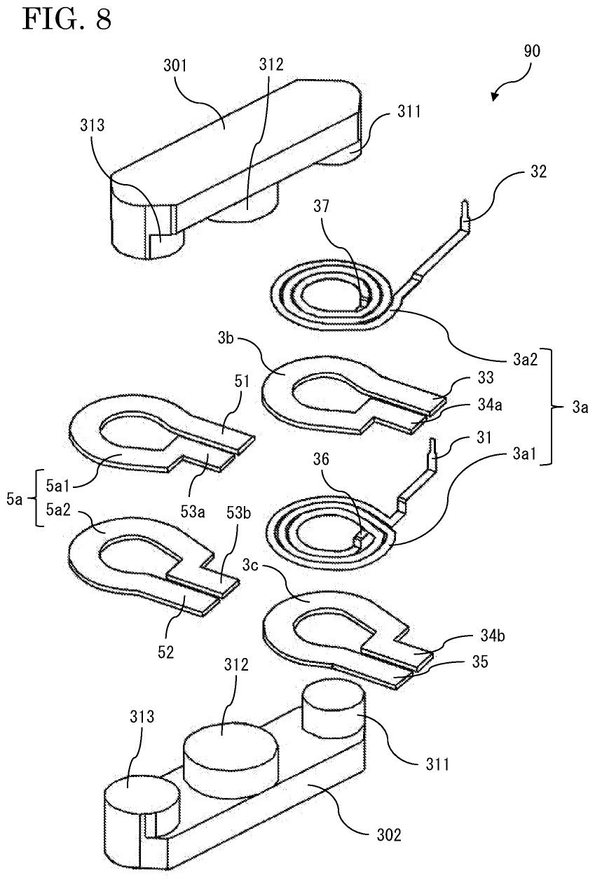

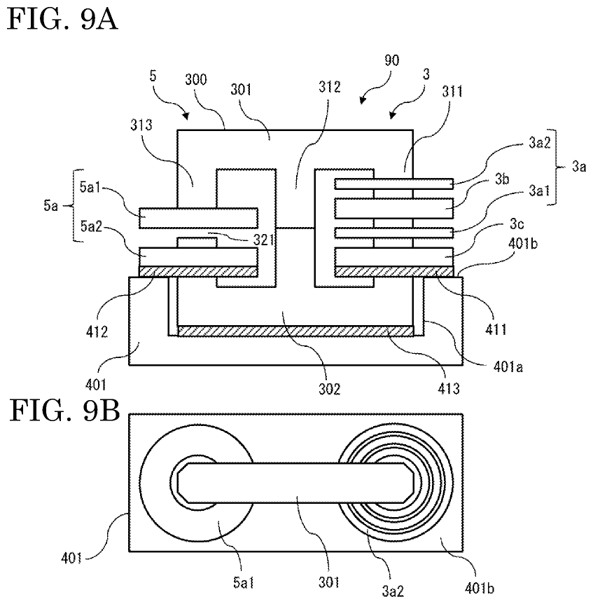

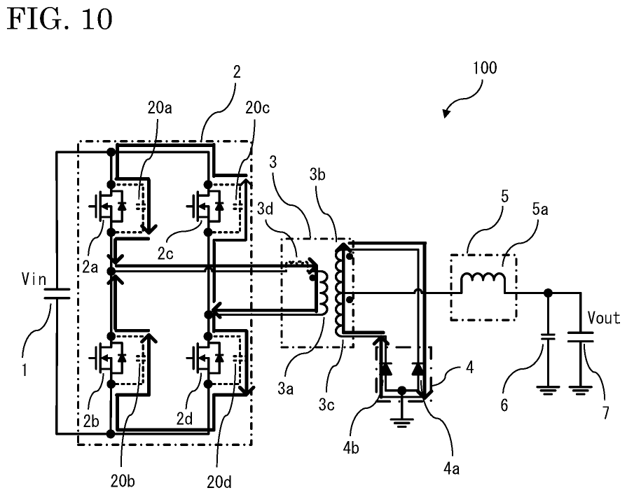

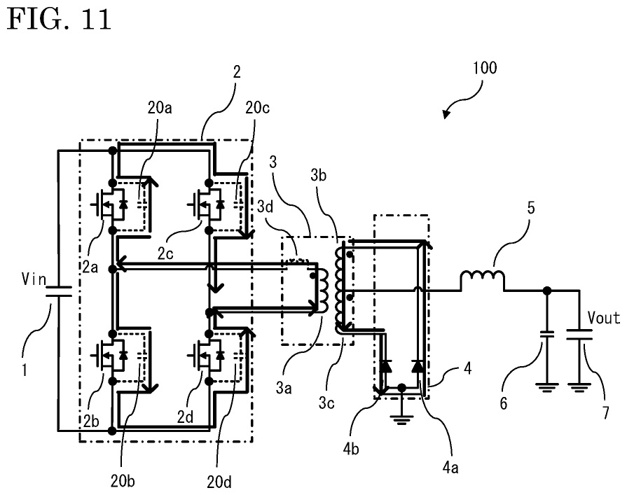

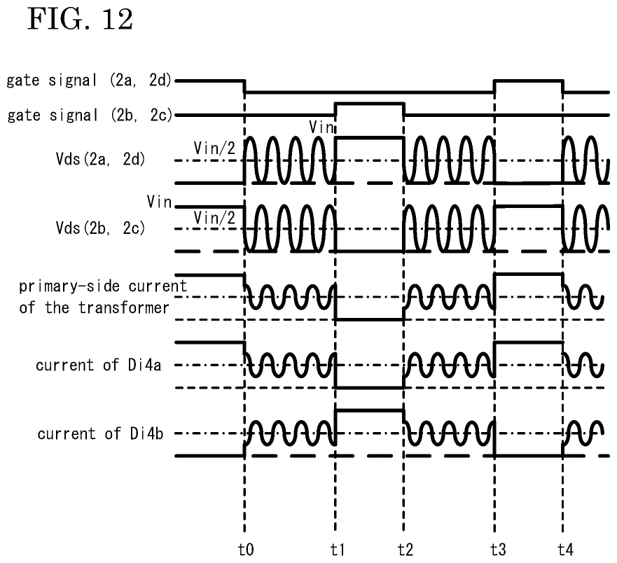

FIG. 1 shows an example of a circuit configuration of a power conversion device 100 according to a first embodiment. FIG. 2 is a schematic diagram showing a configuration of an insulation transformer 3 and a smoothing reactor 5 which are magnetic parts 90 of the power conversion device 100. Each of FIG. 3, FIG. 5, FIG. 6, FIG. 10, and FIG. 11 shows operation of the circuit of the power conversion device 100 and shows paths of current flowing through the circuit. Each of FIG. 4 and FIG. 7 shows magnetic fluxes generated in the magnetic parts 90 of the power conversion device 100 and shows the orientations of the magnetic fluxes in a core 300. FIG. 8 is an exploded perspective view schematically showing the magnetic parts 90 of the power conversion device 100. FIGS. 9A and 9B each schematically show the magnetic parts 90 and a cooler 401 of the power conversion device 100. FIG. 12 shows operation waveforms in the circuit of the power conversion device 100. The power conversion device 100 is a DC/DC converter for converting an input voltage Vin of a DC power supply 1 into a DC voltage on a secondary side insulated by the insulation transformer 3 and for outputting an output voltage Vout to a load such as a battery. The power conversion device 100 is not limited to the DC/DC converter.

### <Power Conversion Device 100>

An example of the circuit configuration of the power conversion device 100 will be described with reference to FIG. 1. In FIG. 1, the left side is an input side, and the right side is an output side. The DC power supply 1 is connected to the input side of the power conversion device 100, and the load (not shown) such as a low-voltage battery is connected to the output side of the power conversion device 100. Although a specific configuration provided with the insulation transformer 3 and the smoothing reactor 5 shown in FIG. 1 will be described as the configuration of the power conversion device 100 in the present embodiment, the power conversion device 100 may have a configuration provided with a full-bridge circuit 2, a rectification circuit 4, and a smoothing capacitor 6. The power conversion device 100 includes: the full-bridge circuit 2 which is connected to the DC power supply 1, has a plurality of semiconductor switching elements 2a, 2b, 2c, and 2d, converts an inputted DC voltage into an AC voltage, and outputs the AC voltage; the insulation transformer 3 which converts the voltage of the AC power outputted from the full-bridge circuit 2 and outputs the resultant voltage; the rectification circuit 4 having rectifier diodes 4a and 4b for rectifying the output of the insulation transformer 3; and the smoothing reactor 5 and the smoothing capacitor 6 which smooth the output of the insulation transformer 3. The output of the insulation transformer 3 is outputted as the output voltage Vout to a load 7 via the smoothing reactor 5 and the smoothing capacitor 6.

The full-bridge circuit 2 has the plurality of semiconductor switching elements 2a, 2b, 2c, and 2d. Although the full-bridge circuit 2 has four semiconductor switching elements in the present embodiment, the number of the semiconductor switching elements is not limited to four. Each of the semiconductor switching elements is, for example, a metal-oxide-semiconductor field-effect transistor (MOSFET) having a built-in diode between the source and the drain thereof. The semiconductor switching element is not limited to the MOSFET and may be a self-turn-off semiconductor switching element such as an insulated-gate bipolar transistor (IGBT) to which a diode is connected in antiparallel. The semiconductor switching element is formed on a semiconductor substrate made from a semiconductor material such as silicon (Si), silicon carbide (SiC), or gallium nitride (GaN). A wide-bandgap semiconductor made from SiC, GaN, or the like may be used for the semiconductor switching element.

The insulation transformer 3 has a primary-side coil 3a and secondary-side coils 3b and 3c. The primary-side coil 3a has primary-side terminals 31 and 32 at end portions of the primary-side coil 3a. The primary-side terminals 31 and 32 are connected to the output side of the full-bridge circuit 2. The secondary-side coil 3b has a center tap terminal 34 and a secondary-side terminal 33 at end portions of the secondary-side coil 3b. The secondary-side coil 3c has the center tap terminal 34 and a secondary-side terminal 35 at end portions of the secondary-side coil 3c. The center tap terminal 34 is connected to the smoothing reactor 5.

The rectification circuit 4 has the rectifier diodes 4a and 4b which are rectifier elements implemented by semiconductor elements. The secondary-side terminals 33 and 35 are respectively connected to cathodes of the rectifier diodes 4a and 4b. Although two rectifier diodes are provided and each of the rectifier diodes is shown as one diode in the present embodiment, the rectifier diode may be composed of two or more diodes connected in parallel. As the rectifier element, a self-turn-off semiconductor switching element such as a MOSFET may be used. The smoothing reactor 5 has a smoothing coil 5a. The smoothing coil 5a has reactor terminals 51 and 52 at end portions of the smoothing coil 5a. The reactor terminal 51 is connected to the center tap terminal 34, and the reactor terminal 52 is connected to the smoothing capacitor 6 and the load 7.

The DC power supply 1 is, for example, an electrolytic capacitor. A configuration may be employed in which a power converter such as an AC/DC converter is connected to a stage preceding the DC power supply 1. Although the full-bridge circuit 2 has been presented as an example of a primary-side circuit, a configuration with another circuit may be employed as long as the circuit is one that converts DC voltage into AC voltage, such as a half-bridge converter or a forward converter. Although the center tap rectification circuit has been presented as an example of a secondary-side circuit, a configuration with another circuit may be employed as long as the circuit is one that can rectify AC voltage, such as a full-bridge rectification circuit. The present embodiment employs a configuration in which anode terminals of the rectifier diodes 4a and 4b in the center tap rectification circuit are grounded. Without any limitation thereto, a configuration may be employed in which: the secondary-side terminals 33 and 35 of the insulation transformer 3 are respectively connected to the anode terminals of the rectifier diodes 4a and 4b; cathode terminals of the rectifier diodes 4a and 4b are connected to the smoothing reactor 5; and the center tap terminal 34 of the insulation transformer 3 is grounded.

### <Insulation Transformer 3 and Smoothing Reactor 5>

A constituent that is a main section of the present disclosure and in which the insulation transformer 3 and the smoothing reactor 5 have been unified will be described with reference to FIG. 2. The power conversion device 100 includes: the core 300 forming a magnetic circuit; the primary-side coil 3a wound on the core 300; the secondary-side coils 3b and 3c magnetically coupled to the primary-side coil 3a and wound on the core 300; and the smoothing coil 5a electrically connected to the secondary-side coils 3b and 3c and wound on the core 300. The insulation transformer 3 is formed as a portion composed of the primary-side coil 3a and the secondary-side coils 3b and 3c wound on the core 300, and the smoothing reactor 5 is formed as a portion composed of the smoothing coil 5a wound on the core 300.

The core 300 has a first core 301, a second core 302 opposed to the first core 301 and disposed to be spaced from the first core 301, a center leg 312 which makes connection between a center portion of the first core 301 and a center portion of the second core 302 opposed to each other, and a plurality of side legs which are away from the center leg 312 and each of which makes connection between an end portion of the first core 301 and an end portion of the second core 302 opposed to each other. In the present embodiment, the core 300 has two side legs which are a first side leg 311 and a second side leg 313. The number of the side legs is not limited thereto. In addition, in the present embodiment, the core 300 is divided into cores each having the shape of the letter E, and the two cores are formed in shapes symmetrical with each other about a plane of the division. When the two cores each having the shape of the letter E and obtained by the division are combined with each other, the center leg 312, the first side leg 311, and the second side leg 313 are formed. Although the core 300 is divided into cores each having the shape of the letter E, the manner of division is not limited thereto, and the core 300 may be divided into a core having the shape of the letter E and a core having the shape of the letter I. If the core 300 is divided into a core having the shape of the letter E and a core having the shape of the letter I, the core having the shape of the letter E is provided with the center leg 312, the first side leg 311, and the second side leg 313, and the core having the shape of the letter I is not provided with any of these legs but is formed in the shape of a rod. In addition, in the present embodiment, the second side leg 313 is provided with a gap portion 321.

The primary-side coil 3a and the secondary-side coils 3b and 3c are wound on the first side leg 311, the smoothing coil 5a is wound on the second side leg 313, and a magnetic path common to the primary-side coil 3a, the secondary-side coils 3b and 3c, and the smoothing coil 5a is formed on the center leg 312.

With such a configuration, only the windings of the insulation transformer 3 are present between the center leg 312 and the first side leg 311, and only the winding of the smoothing reactor 5 is present between the center leg 312 and the second side leg 313. In the configuration described in cited document 1, both the windings of the insulation transformer and the winding of the smoothing reactor are provided between the center leg and the side legs. Since only the windings of the insulation transformer 3 are present between the center leg 312 and the first side leg 311, and only the winding of the smoothing reactor 5 is present between the center leg 312 and the second side leg 313, regions for windings that should be ensured between the center leg 312 and the first side leg 311 and between the center leg 312 and the second side leg 313 are decreased. Consequently, it is possible to downsize the core 300 and decrease cost therefor while decreasing the number of parts through unification of the insulation transformer 3 and the smoothing reactor 5. Since the core 300 is downsized and cost therefor is decreased, it is possible to downsize the power conversion device 100 and decrease cost therefor.

In addition, although the cross-sectional area of a portion, of the core, that shares magnetic paths of the insulation transformer 3 and the smoothing reactor 5 needs to include a cross-sectional area for preventing saturation of the insulation transformer 3 and a cross-sectional area for preventing saturation of the smoothing reactor 5, since the only portion, of the core, that shares the magnetic paths of the insulation transformer 3 and the smoothing reactor 5 is the center leg 312, a region in which the cross-sectional area of the portion of the core for sharing the magnetic paths is to be increased can be minimized, the volume of the core 300 can be decreased, and cost for the core 300 can be decreased.

### <Operation of DC/DC Converter>

Operation of the DC/DC converter will be described with reference to FIG. 3 to FIG. 7. As shown in FIG. 3, in a period during which the semiconductor switching elements 2a and 2d are ON, the semiconductor switching elements 2b and 2c are turned off first, whereby current flows from the DC power supply 1 through the semiconductor switching element 2a, the primary-side coil 3a of the insulation transformer 3, and the semiconductor switching element 2d in this order. On the secondary side, current simultaneously flows through the secondary-side coil 3c of the insulation transformer 3, the smoothing reactor 5, the load 7, and the rectifier diode 4b in this order. The orientations of magnetic fluxes generated in the core 300 during this operation will be described with reference to FIG. 4. In FIG. 4, the orientations of magnetic fluxes (magnetic fluxes 41, 42, 43, 61, 62, and 63) are indicated by arrows. A magnetic flux of the insulation transformer 3 flows (as a magnetic flux 41) from the first side leg 311 on which the primary-side coil 3a is wound. Then, the magnetic flux passes through the first core 301 and the center leg 312 (as a magnetic flux 42). Then, the magnetic flux flows via the second core 302 (as a magnetic flux 43), to return to the first side leg 311. Likewise, a magnetic flux of the smoothing reactor 5 flows (as a magnetic flux 61) from the second side leg 313 on which the smoothing coil 5a is wound. Then, the magnetic flux passes through the first core 301 and the center leg 312 (as a magnetic flux 62). Then, the magnetic flux flows via the second core 302 (as a magnetic flux 63), to return to the second side leg 313.

Next, as shown in FIG. 5, the semiconductor switching elements 2a, 2b, 2c, and 2d are turned off, whereby, on the primary side, no current flows, and, on the secondary side, current flows through the rectifier diodes 4a and 4b, the secondary-side coils 3b and 3c of the insulation transformer 3, the smoothing reactor 5, and the load 7 in this order. At this time, no voltage is applied to the primary-side coil 3a of the insulation transformer 3, and thus the orientation of the magnetic flux generated in the core 300 at the insulation transformer 3 is the same as the orientation of the corresponding magnetic flux shown in FIG. 4. In addition, no voltage is applied to the secondary-side coils 3b and 3c of the insulation transformer 3. Thus, the voltage of the load 7 is applied to the smoothing reactor 5, and the magnetic flux of the core 300 at the smoothing reactor 5 gradually decreases. However, since the direction of current flowing through the smoothing coil 5a is not changed, the orientation of the magnetic flux generated in the core 300 at the smoothing reactor 5 is the same as the orientation of the corresponding magnetic flux shown in FIG. 4.

Next, as shown in FIG. 6, in a period during which the semiconductor switching elements 2b and 2c are ON, the semiconductor switching elements 2a and 2d are turned off, whereby current flows from the DC power supply 1 through the semiconductor switching element 2c, the primary-side coil 3a of the insulation transformer 3, and the semiconductor switching element 2b in this order. On the secondary side, current simultaneously flows through the secondary-side coil 3b of the insulation transformer 3, the smoothing reactor 5, the load 7, and the rectifier diode 4a in this order. The orientations of magnetic fluxes generated in the core 300 during this operation will be described with reference to FIG. 7. In FIG. 7, the orientations of magnetic fluxes (magnetic fluxes 44, 45, 46, 64, 65, and 66) are indicated by arrows. A magnetic flux of the insulation transformer 3 flows (as a magnetic flux 44) from the first side leg 311 on which the primary-side coil 3a is wound. Then, the magnetic flux passes through the second core 302 and the center leg 312 (as a magnetic flux 45). Then, the magnetic flux flows via the first core 301 (as a magnetic flux 46), to return to the first side leg 311. Likewise, a magnetic flux of the smoothing reactor 5 flows (as a magnetic flux 64) from the second side leg 313 on which the smoothing coil 5a is wound. Then, the magnetic flux passes through the first core 301 and the center leg 312 (as a magnetic flux 65). Then, the magnetic flux flows via the second core 302 (as a magnetic flux 66), to return to the second side leg 313.

Next, as shown in FIG. 5, the semiconductor switching elements 2a, 2b, 2c, and 2d are turned off, whereby, on the primary side, no current flows, and, on the secondary side, current flows through the rectifier diodes 4a and 4b, the secondary-side coils 3b and 3c of the insulation transformer 3, the smoothing reactor 5, and the load 7 in this order. At this time, no voltage is applied to the primary-side coil 3a of the insulation transformer 3, and thus the orientation of the magnetic flux generated in the core 300 at the insulation transformer 3 is the same as the orientation of the corresponding magnetic flux shown in FIG. 7. In addition, no voltage is applied to the secondary-side coils 3b and 3c of the insulation transformer 3. Thus, the voltage of the load 7 is applied to the smoothing reactor 5, and the magnetic flux of the core 300 at the smoothing reactor 5 gradually decreases. However, since the direction of current flowing through the smoothing coil 5a is not changed, the orientation of the magnetic flux generated in the core 300 at the smoothing reactor 5 is the same as the orientation of the corresponding magnetic flux shown in FIG. 7.

As described above, the semiconductor switching elements 2a and 2d are simultaneously turned on/off and the semiconductor switching elements 2b and 2c are simultaneously turned on/off so as to adjust the proportion between the period during which the semiconductor switching elements 2a and 2d are ON or the semiconductor switching elements 2b and 2c are ON and the period during which the semiconductor switching elements 2a to 2d are OFF, thereby being able to adjust the output voltage Vout.

### <Structures of Insulation Transformer 3 and Smoothing Reactor 5>

Specific structures of the insulation transformer 3 and the smoothing reactor 5 will be described with reference to FIG. 8. Portions corresponding to those in FIG. 2 will be denoted by the same reference characters. The first core 301 is disposed on the upper side of the drawing, and the second core 302 is disposed on the lower side of the drawing. The center leg 312, the first side leg 311, and the second side leg 313 are provided between the first core 301 and the second core 302. In the present embodiment, the center leg 312, the first side leg 311, and the second side leg 313 have columnar shapes. The shapes of the center leg 312, the first side leg 311, and the second side leg 313 are not limited to columnar shapes.

On the first side leg 311, the secondary-side coil 3c, a primary-side coil 3a1, the secondary-side coil 3b, and a primary-side coil 3a2 are disposed in this order from the second core 302 side. In the present embodiment, the primary-side coils 3al and 3a2 are each formed of three turns, and the secondary-side coils 3b and 3c are each formed of one turn. The number of turns of each coil is not limited thereto. An inner terminal 36 of the primary-side coil 3a1 and an inner terminal 37 of the primary-side coil 3a2 are connected to each other, whereby a primary-side coil 3a formed of six turns is formed. The present embodiment is an example in which the primary-side coil 3a is formed of six turns, and the primary-side coil 3a is divided into the primary-side coils 3al and 3a2 in order to suppress increase in the projected area of the primary-side coil 3a. The primary-side coil 3a has a configuration in which the primary-side coil 3al is wound by three turns from the primary-side terminal 31, the inner terminal 36 of a winding portion of the primary-side coil 3al is connected to the inner terminal 37 of a winding portion of the primary-side coil 3a2, the primary-side coil 3a2 is wound by three turns, and arrival at the primary-side terminal 32 is attained.

The secondary-side coils 3b and 3c have a configuration in which the secondary-side coil 3b is wound by one turn from the secondary-side terminal 33, a center tap terminal 34a is connected to a center tap terminal 34b of the secondary-side coil 3c, the secondary-side coil 3c is wound by one turn, and arrival at the secondary-side terminal 35 is attained. The center tap terminals 34a and 34b may be connected to each other by: employing a bent structure in which at least one of the center tap terminals 34a and 34b approaches the other center tap terminal; or providing, for example, a separate member such as a busbar to the outside of the insulation transformer 3. The connection between the inner terminals 36 and 37 of the winding portions, and the connection between the center tap terminals 34a and 34b, are made by means of, for example, TIG welding or fastening with use of screws. Through the connection between the center tap terminals 34a and 34b, the center tap terminal 34 shown in FIG. 1 is formed.

On the second side leg 313, a smoothing coil 5a2 and a smoothing coil 5al are disposed in this order from the second core 302 side. In the present embodiment, the smoothing coils 5al and 5a2 are each formed of one turn. The number of turns of each smoothing coil is not limited thereto. A connection terminal 53a of the smoothing coil 5a1 and a connection terminal 53b of the smoothing coil 5a2 are connected to each other, whereby a smoothing coil 5a formed of two turns is formed. The present embodiment is an example in which the smoothing coil 5a is formed of two turns. The smoothing coil 5a has a configuration in which the smoothing coil 5al is wound by one turn from the reactor terminal 51, the connection terminal 53a is connected to the connection terminal 53b of the smoothing coil 5a2, the smoothing coil 5a2 is wound by one turn, and arrival at the reactor terminal 52 is attained. The connection terminals 53a and 53b may be connected to each other by: employing a bent structure in which at least one of the connection terminals 53a and 53b approaches the other connection terminal; or providing, for example, a separate member such as a busbar to the outside of the smoothing reactor 5. The connection between the) connection terminals 53a and 53b is made by means of, for example, TIG welding or fastening with use of screws.

In the present embodiment, each of the primary-side coil 3a, the secondary-side coils 3b and 3c, and the smoothing coil 5a is formed in a shape of a plate curved on a plane. Each of the insulation transformer 3 and the smoothing reactor 5 is of a planar type in which the flat-plate-shaped coil is used. Employment of the planar type makes it possible to: increase the cross-sectional area of each coil so as to decrease loss; and improve heat dissipation properties so as to suppress increase in the temperature of the coil. Since increase in the temperatures of the coils is suppressed, each coil can be downsized. Since each coil is downsized, it is possible to downsize the power conversion device 100 and decrease cost therefor. In addition, a configuration is employed in which only the coils of the insulation transformer 3 are present between the center leg 312 and the first side leg 311, and only the coil of the smoothing reactor 5 is present between the center leg 312 and the second side leg 313. Consequently, even if the planar type in which the projected area of each coil portion is large is employed, upsizing of the power conversion device 100 can be suppressed.

### <Cooler 401>

A configuration in which the power conversion device 100 has the cooler 401 will be described. FIG. 9A is a side view of the insulation transformer 3, the smoothing reactor 5, and the cooler 401, with a portion of side walls of a recess portion 401a being removed. FIG. 9B is a plan view of the insulation transformer 3, the smoothing reactor 5, and the cooler 401. As shown in FIGS. 9A and 9B, the power conversion device 100 further includes the cooler 401 having the recess portion 401a. A portion, of the second core 302, that is on an opposite side to the first core 301 is thermally connected to a bottom of the recess portion 401a. The primary-side coil 3a or the secondary-side coils 3b and 3c, and the smoothing coil 5a, are thermally connected to a cooling surface 401b as a portion, of the cooler 401, that encloses an opening of the recess portion 401a. A surface, of the cooler 401, that is on an opposite side to the cooling surface 401b may be provided with a cooling structure in which a coolant flows. The coolant is, for example, cooling water. By providing the cooling structure, heat generated from each of the insulation transformer 3 and the smoothing reactor 5 can be further efficiently cooled. In the present embodiment, the secondary-side coil 3c is disposed on the cooler 401 side, and thus the secondary-side coil 3c is thermally connected to the cooling surface 401b. In the present embodiment, the insulation transformer 3 and the smoothing reactor 5 are thermally connected to the cooler 401 at two locations which are the bottom surface of the core 300 and a portion composed of the secondary-side coil 3c and the smoothing coil 5a2. With such a configuration, the insulation transformer 3 and the smoothing reactor 5 can be efficiently cooled by the cooler 401 at the two locations. Since the insulation transformer 3 and the smoothing reactor 5 are efficiently cooled, the power conversion device 100 can be downsized. Hereinafter, details of downsizing will be described.

The present embodiment employs a configuration in which the insulation transformer 3 and the smoothing reactor 5 integrated with each other are cooled from the bottom surface side by the cooler 401. Such cooling from the bottom surface is a simple method involving placement of a heat generation part onto the cooler 401 and is a cooling method that can be realized at low cost. The second core 302 is cooled by the cooler 401 via a cooling member 413. The first core 301 transmits heat via the center leg 312 and the first side leg 311 to the second core 302 and is cooled by the cooler 401 via the cooling member 413. The primary-side coil 3a and the secondary-side coils 3b and 3c are integrated with each other with, for example, a resin member (not shown) in order to retain windings and ensure insulation between the windings. The cooler 401 side of the secondary-side coil 3c is exposed from the resin member, and each coil is cooled from the secondary-side coil 3c side via a cooling member 411 by the cooler 401.

Likewise, the smoothing coils 5al and 5a2 are integrated with each other with, for example, a resin member (not shown) in order to retain windings and ensure insulation between the windings. The cooler 401 side of the smoothing coil 5a2 is exposed from the resin member, and the smoothing coil 5a is cooled from the smoothing coil 5a2 side via a cooling member 412 by the cooler 401. In many cases, steps are formed between the bottom surface of the second core 302 and the windings (the secondary-side coil 3c and the smoothing coil 5a2) at the lowermost surfaces. Thus, in the present embodiment, the cooler 401 is provided with the recess portion 401a for accommodating the second core 302. Without any limitation to the configuration in which the cooler 401 is provided with the recess portion 401a, a configuration may be employed in which protrusions protruding from the cooler 401 in a direction toward the windings (the secondary-side coil 3c and the smoothing coil 5a2) at the lowermost surfaces are provided, and the protrusions and the windings at the lowermost surfaces are thermally connected to each other.

The second core 302 is enclosed by the side walls of the recess portion 401a, and the secondary-side coil 3c and the smoothing coil 5a2 are, at many portions thereof on the cooler 401 side, thermally connected to the cooling surface 401b via the cooling members 411 and 412. Therefore, the primary-side coil 3a, the secondary-side coils 3b and 3c, and the smoothing coil 5a are, at locations thereof that do not overlap with the core 300, cooled by the cooling surface 401b of the cooler 401. Each of the cooling members 411, 412, and 413 is, for example, grease or a gap filler. In order to assuredly fix the core 300 to the cooler 401 via the cooling member 413, the core 300 may be fixed by being pressed with use of springs or the like at portions, of the first core 301, that are on the upper sides of the first side leg 311 or the second side leg 313, for example.

As described above, the insulation transformer 3 and the smoothing reactor 5 are each configured to be of a closed-core type. Therefore, as shown in FIG. 9B which is a view in a direction perpendicular to the cooling surface 401b, the primary-side coil 3a and the secondary-side coils 3b and 3c can be cooled at portions thereof that are on the upper and lower sides and the right side and that do not overlap with the core 300, and the smoothing coil 5a can be cooled at portions thereof that are on the upper and lower sides and the left side and that do not overlap with the core 300. The primary-side coil 3a, the secondary-side coils 3b and 3c, and the smoothing coil 5a can be cooled at many regions of the peripheries thereof, whereby it is possible to downsize the primary-side coil 3a, the secondary-side coils 3b and 3c, and the smoothing coil 5a and decrease costs therefor. In addition, the regions that are ensured in order to dispose therein the respective coils and that are located between the center leg 312 and the first side leg 311 and between the center leg 312 and the second side leg 313 are downsized, whereby it is possible to further downsize the core 300 and further decrease cost therefor. In addition, the first core 301 is cooled via the center leg 312 and the first side leg 311, and thus the length from each portion of the first core 301 to the center leg 312 and the first side leg 311 are shortened, whereby thermal resistances decrease, and it is possible to further downsize the core 300 and further decrease cost therefor.

In the present embodiment, the primary-side coil 3a, the secondary-side coils 3b and 3c, and the smoothing coil 5a have each been exemplified by one that is of the planar type in which a flat-plate-shaped winding is used. In order to efficiently cool each coil of the planar type, the coil is, in many cases, cooled in a direction of a plane of projection that enables the cooling area of the coil to be ensured. Considering this, the projected area of each coil is increased as seen in the direction perpendicular to the cooling surface 401b in order to ensure cooling capability. In addition, a configuration is employed in which only the windings of the insulation transformer 3 are present between the center leg 312 and the first side leg 311, and only the winding of the smoothing reactor 5 is present between the center leg 312 and the second side leg 313. Consequently, the insulation transformer 3 and the smoothing reactor 5 each of which is of the planar type make it possible to minimize a length, in the direction of the plane of projection, that is dominant out of the lengths of regions for windings that should be ensured between the center leg 312 and the first side leg 311 and between the center leg 312 and the second side leg 313. Therefore, the effect of downsizing the core 300 and decreasing cost therefor can be improved. In addition, as described above, the first core 301 is cooled via the center leg 312 and the first side leg 311, and thus, in the insulation transformer 3 and the smoothing reactor 5 each of which is of the planar type, the lengths from each portion of the first core 301 to the center leg 312 and the first side leg 311 are dominant in terms of thermal resistance. Since the dominant lengths can be minimized, the effect of decreasing the thermal resistance is significant, and it is possible to further downsize the core 300 and further decrease cost therefor.

In addition, as seen in the direction perpendicular to the cooling surface 401b, the primary-side coil 3a and the secondary-side coils 3b and 3c can be cooled at portions thereof that are on the upper and lower sides and the right side and that do not overlap with the core 300, and the smoothing coil 5a can be cooled at portions thereof that are on the upper and lower sides and the left side and that do not overlap with the core 300. Consequently, the regions in which the coils of the planar type are cooled are upsized, whereby the coils can be efficiently cooled. As a result, it is possible to downsize the primary-side coil 3a and the secondary-side coils 3b and 3c of the insulation transformer 3, and the smoothing coil 5a, and decrease costs therefor. In addition, the regions that are ensured in order to dispose therein the respective coils and that are located between the center leg 312 and the first side leg 311 and between the center leg 312 and the second side leg 313 are downsized, whereby it is possible to further downsize the core 300 and further decrease cost therefor.

### <Full-Bridge Circuit 2>

In the description made above, focus is placed on the structures of the insulation transformer 3 and the smoothing reactor 5 which compose the main section of the present disclosure. As shown in FIG. 1, the power conversion device 100 includes the full-bridge circuit 2 as a power conversion circuit which has the plurality of semiconductor switching elements 2a, 2b, 2c, and 2d and which performs conversion between DC power and AC power. The primary-side coil 3a is electrically connected to the output side of the full-bridge circuit 2, and the full-bridge circuit 2 is a circuit employing a hard-switching method in which ON/OFF duty ratios of the plurality of semiconductor switching elements 2a, 2b, 2c, and 2d are changed to adjust output power.

In the present embodiment, an example in which the hard-switching method is employed has been described. In the hard-switching method, as described above, the semiconductor switching elements 2a and 2d are simultaneously turned on/off and the semiconductor switching elements 2b and 2c are simultaneously turned on/off so as to adjust the proportion between the ON period and the OFF period, thereby adjusting the output voltage Vout. An advantageous effect obtained when the hard-switching method is employed will be described with reference to FIG. 10 to FIG. 12. FIG. 10 and FIG. 11 each show a detailed circuit operation performed while the semiconductor switching elements 2a to 2d are OFF. When the state of each of the semiconductor switching elements 2a and 2d is changed from an ON state to an OFF state, a leakage inductance 3d of the insulation transformer 3 attempts to keep current flowing through the primary-side coil 3a of the insulation transformer 3, which is not explained in the descriptions made above with reference to FIG. 3, FIG. 5, and FIG. 6. Therefore, current flows through the leakage inductance 3d, the primary-side coil 3a, a parasitic capacitance 20d of the semiconductor switching element 2d, a parasitic capacitance 20b of the semiconductor switching element 2b, and the leakage inductance 3d of the insulation transformer 3 in this order as shown in FIG. 10. In addition, current flows through the leakage inductance 3d, the primary-side coil 3a, a parasitic capacitance 20c of the semiconductor switching element 2c, a parasitic capacitance 20a of the semiconductor switching element 2a, and the leakage inductance 3d in this order. At this time, the parasitic capacitances 20a and 20d are charged, and the parasitic capacitances 20b and 20c undergo discharge.

When the parasitic capacitances 20a and 20d have been charged to the input voltage Vin, the parasitic capacitances 20b and 20c have undergone discharge to 0 V, and there is no current any more in the leakage inductance 3d, the parasitic capacitances 20a and 20d undergo discharge. At this time, as shown in FIG. 11, current flows on a path extending through the parasitic capacitance 20d, the primary-side coil 3a, the leakage inductance 3d, the parasitic capacitance 20b, and the parasitic capacitance 20d, and a path extending through the parasitic capacitance 20a, the parasitic capacitance 20c, the primary-side coil 3a, the leakage inductance 3d, and the parasitic capacitance 20a. At this time, the parasitic capacitances 20b and 20c are charged. When the parasitic capacitances 20b and 20c have been charged to approximately the input voltage Vin, the parasitic capacitances 20a and 20d have undergone discharge to approximately 0 V, and current of the leakage inductance 3d has become zero, the parasitic capacitances 20b and 20c undergo discharge so that the current paths in FIG. 10 are formed again. In this manner, the circuit operations shown in FIG. 10 and FIG. 11 are repeated.

The waveforms of respective portions at the time of the above circuit operation will be described with reference to FIG. 12. In FIG. 12, the horizontal axis indicates time, and the vertical axis indicates the amplitudes of the respective waveforms. Before t0, the semiconductor switching elements 2a and 2d are ON, and the semiconductor switching elements 2b and 2c are OFF. At t0, the semiconductor switching elements 2a and 2d are turned off. From t0 to t1, the above circuit operations in FIG. 10 and FIG. 11 are repeated. The period from t1 to t2 is a period during which the semiconductor switching elements 2b and 2c are ON and the semiconductor switching elements 2a and 2d are OFF. At t2, the semiconductor switching elements 2b and 2c are turned off. At t2, current flows through the leakage inductance 3d in a direction opposite to the direction at t1, and thus the circuit operation in FIG. 11 is performed. When the parasitic capacitances 20b and 20c have been charged to the input voltage Vin, the parasitic capacitances 20a and 20d have undergone discharge to 0 V, and there is no current any more in the leakage inductance 3d, the circuit operation in FIG. 10 is performed. From t2 to t3, the same circuit operations as those performed from t0 to t1 are performed. The amplitude of vibration from t0 to t1 and the amplitude of vibration from t2 to t3 are assumed to be equal to each other for simplification. However, in actuality, the amplitude gradually decreases since energy is consumed by resistance components on the current paths in FIG. 10 and FIG. 11.

At this time, portions of the core 300 at the insulation transformer 3 (magnetic flux paths formed on the first side leg 311, the first core 301, the center leg 312, and the second core 302), and the primary-side coil 3a and the secondary-side coils 3b and 3c of the insulation transformer 3, generate heat owing to vibrations that occur from t0 to t1 and from t2 to t3. In the present embodiment, the primary-side coil 3a and the secondary-side coils 3b and 3c are wound on the first side leg 311, the smoothing coil 5a is wound on the second side leg 313, and magnetic paths of the insulation transformer 3 and the smoothing reactor 5 are shared at the center leg 312. Therefore, only the coils of the insulation transformer 3 are present between the center leg 312 and the first side leg 311, and only the coil of the smoothing reactor 5 is present between the center leg 312 and the second side leg 313. Thus, it is possible to minimize the lengths in the direction of the plane of projection of the regions for coils that should be ensured between the center leg 312 and the respective side legs. Therefore, as described above, in the case of performing low-cost cooling from the bottom surface, the first core 301 is cooled via the center leg 312 and the first side leg 311, and thus, in the insulation transformer 3, the lengths from each portion of the first core 301 to the center leg 312 and the first side leg 311 can be minimized. Consequently, the thermal resistance of the core 300 decreases, and, with the hard-switching method in which loss in the core 300 is large, the effect of downsizing the core 300 and decreasing cost therefor can be improved.

In addition, the magnetic paths of the insulation transformer 3 and the smoothing reactor 5 are shared at the center leg 312. Consequently, the cross-sectional area of the center leg 312 needs to include the cross-sectional area for preventing saturation of the insulation transformer 3 (the cross-sectional area of the first side leg 311) and the cross-sectional area for preventing saturation of the smoothing reactor 5 (the cross-sectional area of the second side leg 313) and becomes larger than the cross-sectional area of the insulation transformer 3. Therefore, the thermal resistance of the center leg 312 decreases, and thus, in the insulation transformer 3, thermal resistance from each portion of the first core 301 to the cooler 401 decreases. Therefore, with the hard-switching method in which loss in the core 300 is large, additional cost (for upsizing of the core, addition of a cooling member, or the like) arising from thermal feasibility of the core 300 can be decreased.

In addition, a configuration is employed in which the primary-side coil 3a and the secondary-side coils 3b and 3c are wound on the first side leg 311, the smoothing coil 5a is wound on the second side leg 313, and the magnetic paths of the insulation transformer 3 and the smoothing reactor 5 are shared at the center leg 312. Thus, the smoothing coil 5a is physically away from the primary-side coil 3a and the secondary-side coils 3b and 3c through which oscillating current generated through the hard-switching method flows. Therefore, the smoothing coil 5a is less likely to receive noises radiated from the primary-side coil 3a and the secondary-side coils 3b and 3c, and noise outputted from the power conversion device 100 can be decreased. Consequently, it is possible to downsize a noise filter necessary for output from the power conversion device 100 and decrease cost for the noise filter. In addition, since the center leg 312 is positioned between the smoothing coil 5a and each of the primary-side coil 3a and the secondary-side coils 3b and 3c, the center leg 312 serves as a shield, whereby noise coupling from the primary-side coil 3a and the secondary-side coils 3b and 3c to the smoothing coil 5a can be further suppressed.

In addition, since the smoothing coil 5a is physically away from the primary-side coil 3a and the secondary-side coils 3b and 3c through which oscillating current generated through the hard-switching method flows, this leads to decrease in thermal interference with the smoothing coil 5a from the primary-side coil 3a and the secondary-side coils 3b and 3c, in which the heat generation amount increases owing to the oscillating current. Consequently, it is possible to downsize the smoothing coil 5a and decrease cost therefor.

### <Configuration of Core 300>

Details of the configuration of the core 300 will be described. In the present embodiment, the center leg 312 has no gap portion across which portions of the center leg 312 are spaced from each other. The present embodiment employs a configuration in which the primary-side coil 3a and the secondary-side coils 3b and 3c are wound on the first side leg 311, the smoothing coil 5a is wound on the second side leg 313, and the magnetic paths of the insulation transformer 3 and the smoothing reactor 5 are shared at the center leg 312. Consequently, no gap portion needs to be provided to the center leg 312 on which no coil is wound and at which the magnetic paths are merely shared, whereby no eddy current due to leakage magnetic flux from a gap portion of the center leg 312 is generated in any of the primary-side coil 3a, the secondary-side coils 3b and 3c, and the smoothing coil 5a which are adjacent to the center leg 312. Since eddy current is inhibited from being generated in each coil, losses in the primary-side coil 3a, the secondary-side coils 3b and 3c, and the smoothing coil 5a can be decreased.

In the present embodiment, a cross-sectional area of the center leg 312 is smaller than a sum of cross-sectional areas of the plurality of respective side legs, i.e., the first side leg 311 and the second side leg 313. A case of using ferrite for the core 300 will be contemplated, for example. On one hand, a change in the voltage applied to the smoothing reactor 5 is comparatively small, and thus loss in the smoothing reactor 5 is small. Meanwhile, since an inductance value needs to be ensured for high current, the cross-sectional area of the second side leg 313 is limited owing to a DC superimposition characteristic. On the other hand, comparatively high input voltages are applied on positive and negative sides to the insulation transformer 3, whereby loss in the insulation transformer 3 is large. Thus, the cross-sectional area of the first side leg 311 is limited owing to thermal feasibility. Therefore, the cross-sectional area of the center leg 312 can be decreased to the cross-sectional area of the smoothing reactor 5 necessary for the DC superimposition characteristic of the smoothing reactor 5 or the cross-sectional area of the insulation transformer 3 necessary for thermal feasibility of the insulation transformer 3. Consequently, upsizing of the core 300 is suppressed, whereby it is possible to downsize the power conversion device 100 and decrease cost therefor.

In the present embodiment, an example has been described in which the center leg 312, the first side leg 311, and the second side leg 313 have columnar shapes, and the primary-side coil 3a, the secondary-side coils 3b and 3c, and the smoothing coil 5a have circular shapes, as shown in FIG. 8. However, no limitation to this example is made. The shape of each of the center leg 312, the first side leg 311, and the second side leg 313 may be the shape of a quadrangular prism as in an ordinary E-E core. In this case, the primary-side coil 3a, the secondary-side coils 3b and 3c, and the smoothing coil 5a each have a quadrangular shape with portions thereof being each curved at a right angle, and are wound on the first side leg 311 and the second side leg 313. With such a configuration, the center leg 312 and each of the primary-side coil 3a, the secondary-side coils 3b and 3c, and the smoothing coil 5a have shapes linearly extending in a mutually matching manner. Consequently, there is no wasted space, and thus upsizing of the core 300 is suppressed. Therefore, it is possible to downsize the power conversion device 100 and decrease cost therefor.

In the present embodiment, the core 300 is made of ferrite. The ferrite is a material used in common for the insulation transformer 3 and the smoothing reactor 5, and thus the insulation transformer 3 and the smoothing reactor 5 can be made of the same material. Since the insulation transformer 3 and the smoothing reactor 5 are made of the same material, cost for the core 300 can be decreased. As described above, loss in the smoothing reactor 5 is small, and the cross-sectional area of the second side leg 313 is limited owing to the DC superimposition characteristic. In addition, comparatively high input voltages are applied on the positive and negative sides to the insulation transformer 3, whereby loss in the insulation transformer 3 is large. Thus, the cross-sectional area of the first side leg 311 is limited owing to thermal feasibility. Therefore, the effect of decreasing the cross-sectional area of the center leg 312 is significant when the insulation transformer 3 and the smoothing reactor 5 are integrated as the core 300 by using ferrite, whereby it is possible to downsize the core 300 and decrease cost therefor.

### <Configuration of Rectification Circuit 4>

As shown in FIG. 1, the power conversion device 100 according to the present embodiment includes the rectification circuit 4 which has the rectifier diodes 4a and 4b as a plurality of rectifier elements and which is electrically connected to the secondary-side coils 3b and 3c. The anode terminals of the respective rectifier diodes 4a and 4b are grounded. Therefore, the secondary-side coils 3b and 3c are directly connected to the smoothing coil 5a via the center tap terminal 34, and thus terminals for connection to the outside of the magnetic parts 90 do not need to be provided to the secondary-side coils 3b and 3c and the smoothing coil 5a, and the secondary-side coils 3b and 3c and the smoothing coil 5a can be connected to each other in the magnetic parts 90. Since the secondary-side coils 3b and 3c and the smoothing coil 5a are connected to each other in the magnetic parts 90, no space for providing therein connection terminals is necessary, whereby the magnetic parts 90 can be downsized. In addition, since no connection terminals need to be provided, cost for parts necessary for connection terminals and machining cost necessary for connection are unnecessary, whereby cost for the power conversion device 100 can be decreased.

<Configurations of Primary-Side Coil 3a and Secondary-Side Coils 3b and 3c>

In the present embodiment, the number of turns of each of the secondary-side coils 3b and 3c is smaller than the number of turns of the primary-side coil 3a. In the present embodiment, an example has been described in which the primary-side coil 3a is formed of six turns, and each of the secondary-side coils 3b and 3c is formed of one turn. As the number of turns of each of the secondary-side coils 3b and 3c decreases, currents of the secondary-side coils 3b and 3c increase, and the projected areas of the secondary-side coils 3b and 3c increase owing to thermal feasibility of the coils. The present embodiment has a configuration in which only the windings of the insulation transformer 3 are present between the center leg 312 and the first side leg 311, and only the winding of the smoothing reactor 5 is present between the center leg 312 and the second side leg 313. Consequently, the regions for coils that should be ensured between the center leg 312 and the first side leg 311 and between the center leg 312 and the second side leg 313 are decreased. Thus, even when the projected areas of the secondary-side coils 3b and 3c are increased, it is possible to downsize the core 300 and decrease cost therefor. As described above, in the case of performing low-cost cooling from the bottom surface, the first core 301 is cooled via the center leg 312 and the first side leg 311, and thus, in the insulation transformer 3, the lengths from each portion of the first core 301 to the center leg 312 and the first side leg 311 can be minimized. Therefore, the effect of decreasing the thermal resistance is significant, and it is possible to further downsize the core 300 and further decrease cost therefor.

In addition, as described above, as seen in the direction perpendicular to the cooling surface 401b, the primary-side coil 3a and the secondary-side coils 3b and 3c can be cooled at portions thereof that are on the upper and lower sides and the right side and that do not overlap with the core 300, and the smoothing coil 5a can be cooled at portions thereof that are on the upper and lower sides and the left side and that do not overlap with the core 300. Therefore, the regions in which the coils are cooled are upsized, whereby each coil can be efficiently cooled. Since each coil can be efficiently cooled, the primary-side coil 3a, the secondary-side coils 3b and 3c, and the smoothing coil 5a can be downsized, whereby it is possible to downsize the power conversion device 100 and decrease cost therefor. In addition, the regions that are ensured in order to dispose therein the respective coils and that are located between the center leg 312 and the first side leg 311 and between the center leg 312 and the second side leg 313 are downsized, whereby it is possible to further downsize the core 300 and further decrease cost therefor.

As described above, in the power conversion device 100 according to the first embodiment, the core 300 has the first core 301, the second core 302 opposed to the first core 301 and disposed to be spaced from the first core 301, the center leg 312 which makes connection between a center portion of the first core 301 and a center portion of the second core 302 opposed to each other, and the plurality of side legs which are away from the center leg 312 and each of which makes connection between an end portion of the first core 301 and an end portion of the second core 302 opposed to each other, the primary-side coil 3a and the secondary-side coils 3b and 3c are wound on the first side leg 311, the smoothing coil 5a is wound on the second side leg 313, and the magnetic path common to the primary-side coil 3a, the secondary-side coils 3b and 3c, and the smoothing coil 5a is formed on the center leg 312. Consequently, only the windings of the insulation transformer 3 are present between the center leg 312 and the first side leg 311, and only the winding of the smoothing reactor 5 is present between the center leg 312 and the second side leg 313. Therefore, the regions for windings that should be ensured between the center leg 312 and the first side leg 311 and between the center leg 312 and the second side leg 313 can be decreased. Since the regions for windings that should be ensured between the center leg 312 and the first side leg 311 and between the center leg 312 and the second side leg 313 are decreased, it is possible to downsize the core 300 and decrease cost therefor while decreasing the number of parts through unification of the insulation transformer 3 and the smoothing reactor 5. Since the core 300 is downsized and cost therefor is decreased, it is possible to downsize the power conversion device 100 and decrease cost therefor.

In a case where each of the primary-side coil 3a, the secondary-side coils 3b and 3c, and the smoothing coil 5a is formed in a shape of a plate curved on a plane, since each of the insulation transformer 3 and the smoothing reactor 5 is of the planar type in which the flat-plate-shaped coil is used, it is possible to: increase the cross-sectional area of each coil so as to decrease loss; and improve heat dissipation properties so as to suppress increase in the temperature of the coil. Since increase in the temperatures of the coils is suppressed, each coil can be downsized. Since each coil is downsized, it is possible to downsize the power conversion device 100 and decrease cost therefor. In addition, a configuration is employed in which only the coils of the insulation transformer 3 are present between the center leg 312 and the first side leg 311, and only the coil of the smoothing reactor 5 is present between the center leg 312 and the second side leg 313. Consequently, even if the planar type in which the projected area of each coil portion is large is employed, upsizing of the power conversion device 100 can be suppressed.

In a case where the power conversion device 100 includes the full-bridge circuit 2 as a power conversion circuit which has the plurality of semiconductor switching elements 2a, 2b, 2c, and 2d and which performs conversion between DC power and AC power, the primary-side coil 3a is electrically connected to the output side of the full-bridge circuit 2, and the full-bridge circuit 2 is a circuit employing a hard-switching method in which ON/OFF duty ratios of the plurality of semiconductor switching elements 2a, 2b, 2c, and 2d are changed to adjust output power, the core 300 in the present disclosure has been downsized, and thus, even with the hard-switching method in which loss in the core 300 is large, the thermal resistance of the core 300 is decreased, whereby the effect of downsizing the core 300 and decreasing cost therefor can be improved.

In a case where the center leg 312 has no gap portion across which portions of the center leg 312 are spaced from each other, since the present disclosure employs a configuration in which the primary-side coil 3a and the secondary-side coils 3b and 3c are wound on the first side leg 311, the smoothing coil 5a is wound on the second side leg 313, and the magnetic paths of the insulation transformer 3 and the smoothing reactor 5 are shared at the center leg 312, no gap portion needs to be provided to the center leg 312 on which no coil is wound and at which the magnetic paths are merely shared, whereby no eddy current due to leakage magnetic flux from a gap portion of the center leg 312 is generated in any of the primary-side coil 3a, the secondary-side coils 3b and 3c, and the smoothing coil 5a which are adjacent to the center leg 312. Since eddy current is inhibited from being generated in each coil, losses in the primary-side coil 3a, the secondary-side coils 3b and 3c, and the smoothing coil 5a can be decreased.

In a case where a cross-sectional area of the center leg 312 is smaller than a sum of cross-sectional areas of the plurality of respective side legs, i.e., the first side leg 311 and the second side leg 313, the configuration of the present disclosure allows the cross-sectional area of the center leg 312 to be decreased to the cross-sectional area of the smoothing reactor 5 necessary for the DC superimposition characteristic of the smoothing reactor 5 or the cross-sectional area of the insulation transformer 3 necessary for thermal feasibility of the insulation transformer 3, and thus upsizing of the core 300 is suppressed, whereby it is possible to downsize the power conversion device 100 and decrease cost therefor.

In a case where the core 300 is made of ferrite, the ferrite is a material used in common for the insulation transformer 3 and the smoothing reactor 5, and thus the insulation transformer 3 and the smoothing reactor 5 can be made of the same material. Since the insulation transformer 3 and the smoothing reactor 5 are made of the same material, cost for the core 300 can be decreased.

In a case where the power conversion device 100 includes the rectification circuit 4 which has the rectifier diodes 4a and 4b as a plurality of rectifier elements and which is electrically connected to the secondary-side coils 3b and 3c, and the anode terminals of the respective rectifier diodes 4a and 4b are grounded, the secondary-side coils 3b and 3c are directly connected to the smoothing coil 5a via the center tap terminal 34, and thus terminals for connection to the outside of the magnetic parts 90 do not need to be provided to the secondary-side coils 3b and 3c and the smoothing coil 5a, and the secondary-side coils 3b and 3c and the smoothing coil 5a can be connected to each other in the magnetic parts 90. Since the secondary-side coils 3b and 3c and the smoothing coil 5a are connected to each other in the magnetic parts 90, no space for providing therein connection terminals is necessary, whereby the magnetic parts 90 can be downsized. In addition, since no connection terminals need to be provided, cost for parts necessary for connection terminals and machining cost necessary for connection are unnecessary, whereby cost for the power conversion device 100 can be decreased.

In a case where the number of turns of each of the secondary-side coils 3b and 3c is smaller than the number of turns of the primary-side coil 3a, as the number of turns of each of the secondary-side coils 3b and 3c decreases, currents of the secondary-side coils 3b and 3c increase, and the projected areas of the secondary-side coils 3b and 3c increase owing to thermal feasibility of the coils. However, in the configuration of the present disclosure, the regions for coils that should be ensured between the center leg 312 and the first side leg 311 and between the center leg 312 and the second side leg 313 are decreased. Thus, even when the projected areas of the secondary-side coils 3b and 3c are increased, it is possible to downsize the core 300 and decrease cost therefor.

In a case where the power conversion device 100 includes the cooler 401 having the recess portion 401a, a portion, of the second core 302, that is on an opposite side to the first core 301 is thermally connected to a bottom of the recess portion 401a, and the primary-side coil 3a or the secondary-side coils 3b and 3c, and the smoothing coil 5a, are thermally connected to the cooling surface 401b as a portion, of the cooler 401, that encloses an opening of the recess portion 401a, the insulation transformer 3 and the smoothing reactor 5 are thermally connected to the cooler 401 at two locations which are the bottom surface of the core 300 and the portion composed of the primary-side coil 3a or the secondary-side coils 3b and 3c and the smoothing coil 5a2, whereby the insulation transformer 3 and the smoothing reactor 5 can be efficiently cooled by the cooler 401 at the two locations. Since the insulation transformer 3 and the smoothing reactor 5 are efficiently cooled, the power conversion device 100 can be downsized.

### Second Embodiment

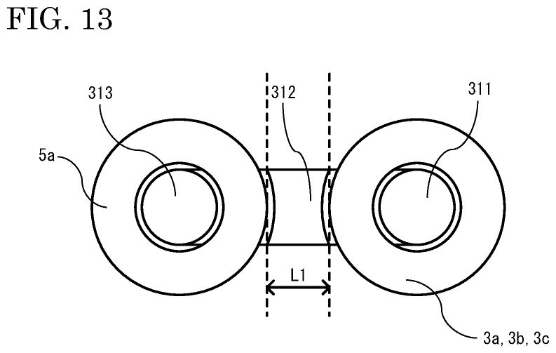

A power conversion device 100 according to a second embodiment will be described. FIG. 13 is a plan view schematically showing a main section of the power conversion device 100 according to the second embodiment, with the first core 301 being removed from the magnetic parts 90. In FIG. 13, each of the primary-side coil 3a, the secondary-side coils 3b and 3c, and the smoothing coil 5a has a disc shape shown merely as an external shape for simplification. In the power conversion device 100 according to the second embodiment, the configuration of the center leg 312 differs from that in the first embodiment.

In the first embodiment, an example in which the center leg 312 has a columnar shape has been described. The center leg 312 is disposed to be spaced from each of the primary-side coil 3a, the secondary-side coils 3b and 3c, and the smoothing coil 5a which are disposed to be adjacent to the center leg 312. In the present embodiment, side surfaces of the center leg 312 have shapes that match shapes of respective side surfaces of the primary-side coil 3a, the secondary-side coils 3b and 3c, and the smoothing coil 5a which are opposed to the side surfaces of the center leg 312. Since the primary-side coil 3a, the secondary-side coils 3b and 3c, and the smoothing coil 5a have disc shapes, the center leg 312 has a shape with the center thereof being narrowed.

In a case where the center leg 312 is formed in a columnar shape, wasted spaces are present between the center leg 312 and each of the primary-side coil 3a and the secondary-side coils 3b and 3c and between the center leg 312 and the smoothing coil 5a. Meanwhile, with the present configuration, the wasted spaces can be reduced, and thus the distance (distance L1 in FIG. 13) between the smoothing coil 5a and each of the primary-side coil 3a and the secondary-side coils 3b and 3c can be shortened. Since the distance L1 is shortened, the distance between the first side leg 311 and the second side leg 313 is also shortened, whereby the core 300 can be downsized. Since the core 300 is downsized, it is possible to downsize the power conversion device 100 and decrease cost therefor.

### Third Embodiment

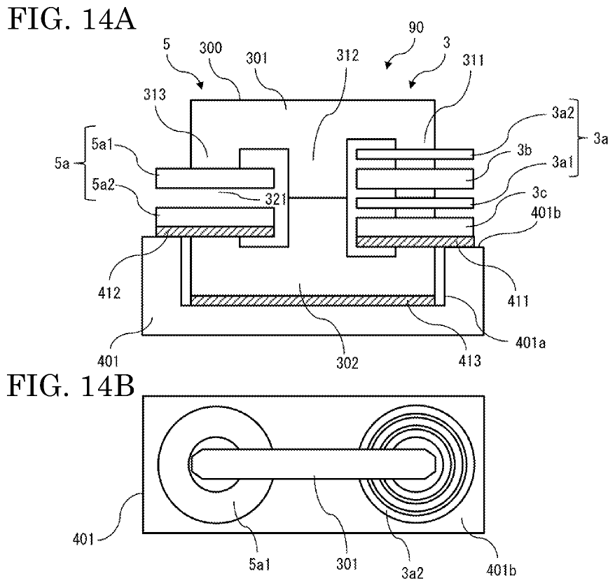

A power conversion device 100 according to a third embodiment will be described. FIGS. 14A and 14B each schematically show magnetic parts 90 of the power conversion device 100 according to the third embodiment. FIG. 14A is a side view showing the insulation transformer 3, the smoothing reactor 5, and the cooler 401, with a portion of the side walls of the recess portion 401a being removed. FIG. 14B is a plan view of the insulation transformer 3, the smoothing reactor 5, and the cooler 401. In the power conversion device 100 according to the third embodiment, the configuration of the core 300 differs from that in the first embodiment.

A thickness of one or both of portions, of the first core 301 and the second core 302, with which a magnetic flux of the smoothing coil 5a interlinks is larger than a thickness of each of the first core 301 and the second core 302 with which magnetic fluxes of the primary-side coil 3a and the secondary-side coils 3b and 3c interlink. In the configuration of the magnetic parts 90 shown in FIG. 14A, the thickness of both of said portions of the first core 301 and the second core 302 is set to be larger than the thickness of each of the first core 301 and the second core 302 with which magnetic fluxes of the primary-side coil 3a and the secondary-side coils 3b and 3c interlink.

The insulation transformer 3 is provided with the primary-side coil 3a and the secondary-side coils 3b and 3c, and thus the total thickness of the coils tends to be larger than that of the smoothing reactor 5. Therefore, wasted spaces are present between the smoothing coil 5a and the first core 301 and between the smoothing coil 5a and the second core 302. Considering this, the thicknesses of the first core 301 and the second core 302 are increased so as to fill the wasted spaces. Consequently, as shown in FIG. 14B which is a view in the direction perpendicular to the cooling surface 401b, the sizes in the short-side direction of the first core 301 and the second core 302 can be decreased, and the projected areas of the insulation transformer 3 and the smoothing reactor 5 can be decreased. This is more effective when the sizes in the short-side direction of the first core 301 and the second core 302 are determined according to a restriction on the cross-sectional area of the smoothing reactor 5, as seen in the direction perpendicular to the cooling surface 401b.

### Fourth Embodiment

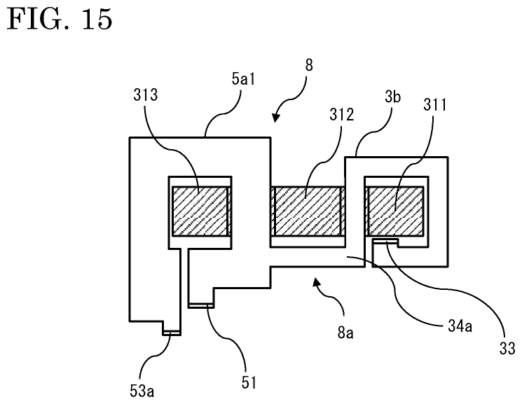

A power conversion device 100 according to a fourth embodiment will be described. FIG. 15 schematically shows magnetic parts 90 of the power conversion device 100 according to the fourth embodiment and shows a secondary-side coil 3b and a smoothing coil 5a1, with the first core 301 being removed from the magnetic parts 90. The power conversion device 100 according to the fourth embodiment has a configuration in which the secondary-side coil 3b and the smoothing coil 5al have been integrated with each other.

The secondary-side coil 3b and the smoothing coil 5al are formed as an integrated coil member 8 in which the secondary-side coil 3b and the smoothing coil 5al have been arranged side-by-side and have been electrically and mechanically coupled together by an integration portion 8a. The integration portion 8a is a portion at which the center tap terminal 34a and the reactor terminal 51 have been coupled together. In the present embodiment, each of the center leg 312, the first side leg 311, and the second side leg 313 has a shape of a quadrangular prism. Each of the primary-side coil 3a, the secondary-side coils 3b and 3c, and the smoothing coil 5a has a quadrangular shape with portions thereof being each curved at a right angle.

With such a configuration, the integrated coil member 8 is formed of, for example, a single sheet metal part, and thus the number of parts as coils decreases. Therefore, machining cost for connecting the secondary-side coil 3b and the smoothing coil 5al becomes unnecessary, whereby costs for the magnetic parts 90 can be decreased. In addition, since there is no need for any region required for connection in the magnetic parts 90, the magnetic parts 90 can be downsized.

### Fifth Embodiment

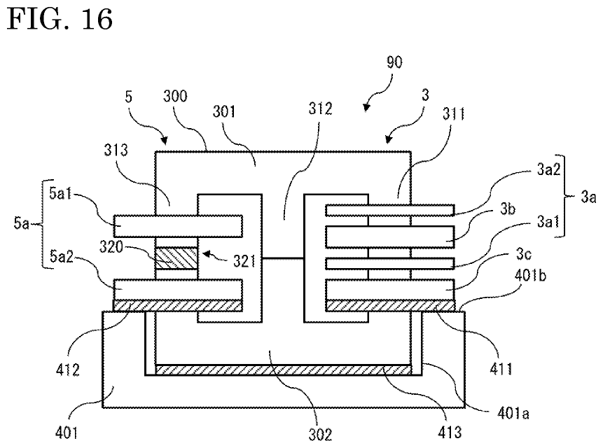

A power conversion device 100 according to a fifth embodiment will be described. FIG. 16 schematically shows magnetic parts 90 of the power conversion device 100 according to the fifth embodiment and is a side view showing the insulation transformer 3, the smoothing reactor 5, and the cooler 401, with a portion of the side walls of the recess portion 401a being removed. In the power conversion device 100 according to the fifth embodiment, the configuration of the core 300 differs from that in the first embodiment.

Any leg, among the center leg 312 and the plurality of side legs, on which a corresponding coil among the primary-side coil 3a, the secondary-side coils 3b and 3c, and the smoothing coil 5a is wound and on which no magnetic path common to the primary-side coil 3a, the secondary-side coils 3b and 3c, and the smoothing coil 5a is formed has the gap portion 321 across which portions of the leg are spaced from each other, and a spacer member 320 is inserted into the gap portion 321. In the present embodiment, the second side leg 313 on which the smoothing coil 5a is wound has the gap portion 321, and the spacer member 320 is inserted into the gap portion 321. The spacer member 320 is made of, for example, a resin member.

In the example shown in FIGS. 9A and 9B regarding the first embodiment, the second side leg 313 on which the smoothing coil 5a is wound has the gap portion 321, and the gap portion 321 is a space provided with no spacer member 320. By inserting the spacer member 320 into the gap portion 321 as shown in FIG. 16, the second side leg 313 can be fixed from an upper portion of the first core 301 at the time of fixing the core 300 to the cooler 401. Since the second side leg 313 is fixed from the upper portion of the first core 301, the vibration resistance at the gap portion 321 of the second side leg 313 can be improved.

### Sixth Embodiment

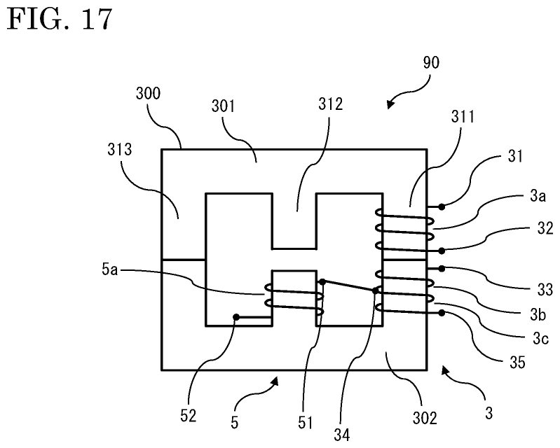

A power conversion device 100 according to a sixth embodiment will be described. FIG. 17 is a schematic diagram showing a configuration of an insulation transformer 3 and a smoothing reactor 5 which are magnetic parts 90 of the power conversion device 100 according to the sixth embodiment. In the power conversion device 100 according to the sixth embodiment, the portion of the core 300 on which a coil is wound differs from that in the first embodiment.

In the present embodiment, the primary-side coil 3a and the secondary-side coils 3b and 3c are wound on the first side leg 311, the smoothing coil 5a is wound on the center leg 312, and the magnetic path common to the primary-side coil 3a, the secondary-side coils 3b and 3c, and the smoothing coil 5a is formed on the second side leg 313. With such a configuration, only the coil of the smoothing reactor 5 is present between the center leg 312 and the second side leg 313, and thus the region for coils that should be ensured between the center leg 312 and the second side leg 313 can be decreased. Since the region for coils is decreased, it is possible to downsize the core 300 and decrease cost therefor while decreasing the number of parts through unification of the insulation transformer 3 and the smoothing reactor 5.

In the present embodiment, a cross-sectional area of the second side leg 313 is smaller than a sum of cross-sectional areas of the center leg 312 and the plurality of side legs excluding the second side leg 313. The cross-sectional area of the portion, of the core 300, that shares the magnetic paths of the insulation transformer 3 and the smoothing reactor 5 needs to include the cross-sectional area for preventing saturation of the insulation transformer 3 and the cross-sectional area for preventing saturation of the smoothing reactor 5. The second side leg 313 sharing the magnetic paths of the insulation transformer 3 and the smoothing reactor 5 is away leftward from the center leg 312 on which only the coil of the smoothing reactor 5 is wound, whereby the region of increase in the cross-sectional area of the second side leg 313 sharing the magnetic paths can be decreased. Since increase in the cross-sectional area of the second side leg 313 is suppressed, increase in the volume of the core 300 is suppressed, whereby cost for the core 300 can be decreased.

The second side leg 313 has no gap portion across which portions of the second side leg 313 are spaced from each other. The present embodiment employs a configuration in which the primary-side coil 3a and the secondary-side coils 3b and 3c are wound on the first side leg 311, the smoothing coil 5a is wound on the center leg 312, and the magnetic paths of the insulation transformer 3 and the smoothing reactor 5 are shared at the second side leg 313. Consequently, no gap portion needs to be provided to the second side leg 313 on which no coil is wound and at which the magnetic paths are merely shared, whereby no eddy current due to leakage magnetic flux from a gap portion of the second side leg 313 is generated in the smoothing coil 5a which is adjacent to the second side leg 313. Since eddy current is inhibited from being generated in the smoothing coil 5a, loss in the smoothing coil 5a can be decreased. In addition, the first side leg 311 and the second side leg 313 as both ends of the core 300 can be fixed from upper portions of the first core 301 at the time of fixing the core 300 to the cooler 401, whereby the vibration resistance of the core 300 can be improved. In addition, the length to the second side leg 313 from each portion that is away leftward from the center leg 312 in the core 300 is shortened, and thus the thermal resistance of the core 300 decreases, whereby it is possible to further downsize the core 300 and further decrease cost therefor.

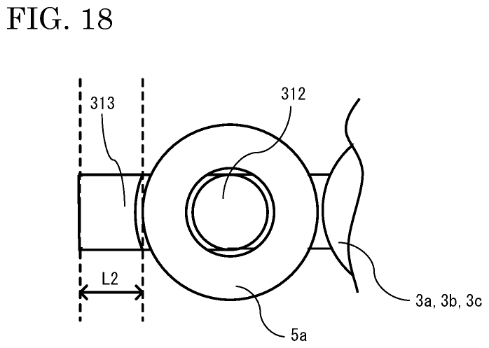

A configuration of other magnetic parts 90 according to the present embodiment will be described. FIG. 18 is a plan view showing a configuration of a portion of the other magnetic parts 90 of the power conversion device 100 according to the sixth embodiment, with the first core 301 being removed from the magnetic parts 90. In FIG. 18, the smoothing coil 5a has a disc shape shown merely as an external shape for simplification. The second side leg 313 is disposed to be spaced from the smoothing coil 5a which is disposed to be adjacent to the second side leg 313, and a side surface of the second side leg 313 has a shape that matches a shape of a side surface of the smoothing coil 5a which is opposed to the side surface of the second side leg 313.

With such a configuration, the wasted space between the second side leg 313 and the smoothing coil 5a can be reduced, and thus the distance (distance L2 in FIG. 18) between an end of the second side leg 313 and the smoothing coil 5a can be shortened. Since the distance L2 is shortened, the distance between the first side leg 311 and the second side leg 313 is also shortened, whereby the core 300 can be downsized. Since the core 300 is downsized, it is possible to downsize the power conversion device 100 and decrease cost therefor.

### Seventh Embodiment

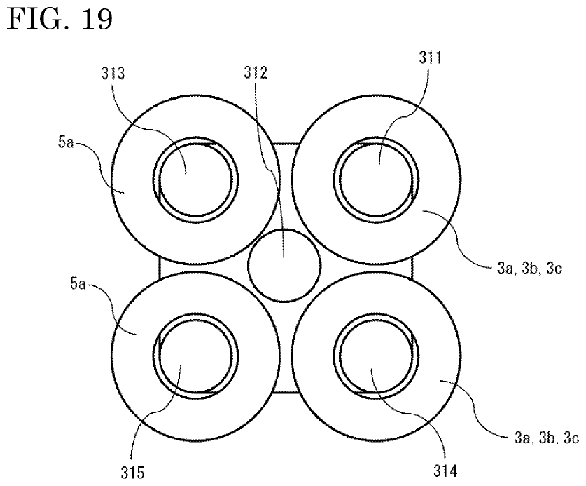

A power conversion device 100 according to a seventh embodiment will be described. FIG. 19 is a plan view showing a configuration of insulation transformers 3 and smoothing reactors 5 which are magnetic parts 90 of the power conversion device 100 according to the seventh embodiment, with the first core 301 being removed from the magnetic parts 90. In FIG. 19, each of the primary-side coil 3a, the secondary-side coils 3b and 3c, and the smoothing coil 5a has a disc shape shown merely as an external shape for simplification. The power conversion device 100 according to the seventh embodiment has a configuration in which the core 300 further includes a plurality of side legs in addition to the constituents in the first embodiment.

In the present embodiment, the plurality of side legs further include a third side leg 314 and a fourth side leg 315 in addition to the first side leg 311 and the second side leg 313, and the first side leg 311, the second side leg 313, the third side leg 314, and the fourth side leg 315 are arranged away from the center leg 312 so as to enclose the center leg 312. In the drawing, the second core 302 is formed such that the external shape thereof is a rectangular shape, and each of the first side leg 311, the second side leg 313, the third side leg 314, and the fourth side leg 315 is provided at a corresponding corner of the second core 302. The external shape of the second core 302 and the arrangement of the side legs are not limited thereto. The primary-side coil 3a and the secondary-side coils 3b and 3c are wound on the third side leg 314, and the smoothing coil 5a is wound on the fourth side leg 315.

The primary-side coil 3a and the secondary-side coils 3b and 3c are wound on two side legs in a divided manner, and the smoothing coil 5a is wound on two side legs in a divided manner. For example, the primary-side coil 3a and the secondary-side coils 3b and 3c are disposed in a parallel relationship on the first side leg 311 and the third side leg 314, and the smoothing coil 5a is disposed in a parallel relationship on the second side leg 313 and the fourth side leg 315. The manner of connection of the coils is not limited thereto. The primary-side coil 3a and the secondary-side coils 3b and 3c may be disposed in a series relationship on the first side leg 311 and the third side leg 314, and the smoothing coil 5a may be disposed in a series relationship on the second side leg 313 and the fourth side leg 315. The primary-side coil 3a, the secondary-side coils 3b and 3c, and the smoothing coil 5a may be divided into coils for the four side legs through an arbitrarily-determined method.

With such a configuration, the coils are disposed in a divided manner, and thus the height of each of the coils and the core 300 can be made low. Even if there are restrictions on heights in arrangement of the power conversion device 100, the power conversion device 100 can be easily installed.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the specification of the present disclosure. For example, at least one of the constituent components may be modified, added, or eliminated. At least one of the constituent components mentioned in at least one of the preferred embodiments may be selected and combined with the constituent components mentioned in another preferred embodiment.

Hereinafter, modes of the present disclosure are summarized as additional notes.

### (Additional Note 1)

A power conversion device comprising:
a core forming a magnetic circuit;
a primary-side coil wound on the core;
a secondary-side coil magnetically coupled to the primary-side coil and wound on the core; and
a smoothing coil electrically connected to the secondary-side coil and wound on the core, wherein
the core has
   a first core,
   a second core opposed to the first core and disposed to be spaced from the first core,
   a center leg which makes connection between a center portion of the first core and a center portion of the second core opposed to each other, and
   a plurality of side legs which are away from the center leg and each of which makes connection between an end portion of the first core and an end portion of the second core opposed to each other,
the primary-side coil and the secondary-side coil are wound on a first side leg among the side legs,
the smoothing coil is wound on a second side leg among the side legs, and
a magnetic path common to the primary-side coil, the secondary-side coil, and the smoothing coil is formed on the center leg.

### (Additional Note 2)

A power conversion device comprising:
a core forming a magnetic circuit;
a primary-side coil wound on the core;
a secondary-side coil magnetically coupled to the primary-side coil and wound on the core; and
a smoothing coil electrically connected to the secondary-side coil and wound on the core, wherein
the core has
   a first core,
   a second core opposed to the first core and disposed to be spaced from the first core,
   a center leg which makes connection between a center portion of the first core and a center portion of the second core opposed to each other, and
   a plurality of side legs which are away from the center leg and each of which makes connection between an end portion of the first core and an end portion of the second core opposed to each other,
the primary-side coil and the secondary-side coil are wound on a first side leg among the side legs,
the smoothing coil is wound on the center leg, and
a magnetic path common to the primary-side coil, the secondary-side coil, and the smoothing coil is formed on a second side leg among the side legs.

### (Additional Note 3)

The power conversion device according to additional note 1 or 2, wherein each of the primary-side coil, the secondary-side coil, and the smoothing coil is formed in a shape of a plate curved on a plane.

### (Additional Note 4)

The power conversion device according to any one of additional notes 1 to 3, further comprising a power conversion circuit which has a plurality of semiconductor switching elements and which performs conversion between DC power and AC power, wherein
the primary-side coil is electrically connected to an output side of the power conversion circuit, and
the power conversion circuit is a circuit employing a hard-switching method in which ON/OFF duty ratios of the plurality of semiconductor switching elements are changed to adjust output power.

### (Additional Note 5)

The power conversion device according to additional note 1 or 3, wherein the center leg has no gap portion across which portions of the center leg are spaced from each other.

### (Additional Note 6)

The power conversion device according to additional note 2 or 3, wherein the second side leg has no gap portion across which portions of the second side leg are spaced from each other.

### (Additional Note 7)

The power conversion device according to additional note 1 or 3, wherein a cross-sectional area of the center leg is smaller than a sum of cross-sectional areas of the plurality of side legs.

### (Additional Note 8)

The power conversion device according to additional note 2 or 3, wherein a cross-sectional area of the second side leg is smaller than a sum of cross-sectional areas of the center leg and the plurality of side legs excluding the second side leg.

### (Additional Note 9)

The power conversion device according to additional note 1 or 3, wherein
the center leg is disposed to be spaced from each of the primary-side coil, the secondary-side coil, and the smoothing coil which are disposed to be adjacent to the center leg, and
side surfaces of the center leg have shapes that match shapes of respective side surfaces of the primary-side coil, the secondary-side coil, and the smoothing coil which are opposed to the side surfaces of the center leg.

### (Additional Note 10)

The power conversion device according to additional note 2 or 3, wherein
the second side leg is disposed to be spaced from the smoothing coil which is disposed to be adjacent to the second side leg, and
a side surface of the second side leg has a shape that matches a shape of a side surface of the smoothing coil which is opposed to the side surface of the second side leg.

### (Additional Note 11)

The power conversion device according to any one of additional notes 1 to 10, wherein a thickness of one or both of portions, of the first core and the second core, with which a magnetic flux of the smoothing coil interlinks is larger than a thickness of each of the first core and the second core with which magnetic fluxes of the primary-side coil and the secondary-side coil interlink.

### (Additional Note 12)

The power conversion device according to any one of additional notes 1 to 11, wherein the core is made of ferrite.

### (Additional Note 13)

The power conversion device according to any one of additional notes 1 to 12, further comprising a rectification circuit which has a plurality of rectifier elements and which is electrically connected to the secondary-side coil, wherein
anode terminals of the plurality of respective rectifier elements are grounded.

### (Additional Note 14)

The power conversion device according to additional note 13, wherein the secondary-side coil and the smoothing coil are formed as an integrated coil member in which the secondary-side coil and the smoothing coil have been arranged side-by-side and have been electrically and mechanically coupled together by an integration portion.

### (Additional Note 15)

The power conversion device according to any one of additional notes 1 to 14, wherein the number of turns of the secondary-side coil is smaller than the number of turns of the primary-side coil.

### (Additional Note 16)

The power conversion device according to any one of additional notes 1 to 15, wherein any leg, among the center leg and the plurality of side legs, on which a corresponding coil among the primary-side coil, the secondary-side coil, and the smoothing coil is wound and on which no magnetic path common to the primary-side coil, the secondary-side coil, and the smoothing coil is formed has a gap portion across which portions of the leg are spaced from each other, and
a spacer member is inserted into the gap portion.

### (Additional Note 17)

The power conversion device according to any one of additional notes 1 to 16, further comprising a cooler having a recess portion, wherein
a portion, of the second core, that is on an opposite side to the first core is thermally connected to a bottom of the recess portion, and
the primary-side coil or the secondary-side coil, and the smoothing coil, are thermally connected to a portion, of the cooler, that encloses an opening of the recess portion.

### (Additional Note 18)

The power conversion device according to additional note 1 or 3, wherein
the plurality of side legs further include a third side leg and a fourth side leg,
the first side leg, the second side leg, the third side leg, and the fourth side leg are arranged away from the center leg so as to enclose the center leg,
the primary-side coil and the secondary-side coil are wound on the third side leg, and
the smoothing coil is wound on the fourth side leg.

### DESCRIPTION OF THE REFERENCE CHARACTERS

1 DC power supply
2 full-bridge circuit
2a, 2b, 2c, 2d semiconductor switching element
3 insulation transformer
3a, 3a1, 3a2 primary-side coil
3b, 3c secondary-side coil
3d leakage inductance
4 rectification circuit
4a, 4b rectifier diode
5 smoothing reactor
5a, 5a1, 5a2 smoothing coil
6 smoothing capacitor
7 load
8 integrated coil member
8a integration portion
20a, 20b, 20c, 20d parasitic capacitance
31, 32 primary-side terminal
33, 35 secondary-side terminal
34, 34a, 34b center tap terminal
36, 37 inner terminal
51, 52 reactor terminal
53a, 53b connection terminal
41, 42, 43, 44, 45, 46, 61, 62, 63, 64, 65, 66 magnetic flux
90 magnetic part
100 power conversion device
300 core
301 first core
302 second core
312 center leg
311 first side leg
313 second side leg
314 third side leg
315 fourth side leg
320 spacer member
321 gap portion
401 cooler
401a recess portion
401b cooling surface
411, 412, 413 cooling member

What is claimed is:

1. A power conversion device comprising:
a core forming a magnetic circuit;
a primary-side coil wound on the core;
a secondary-side coil magnetically coupled to the primary-side coil and wound on the core; and
a smoothing coil electrically connected to the secondary-side coil and wound on the core, wherein
the core has
a first core,
a second core opposed to the first core and disposed to be spaced from the first core,
a center leg which makes connection between a center portion of the first core and a center portion of the second core opposed to each other, and
a plurality of side legs which are away from the center leg and each of which makes connection between an end portion of the first core and an end portion of the second core opposed to each other,
the primary-side coil and the secondary-side coil are wound on a first side leg among the side legs,
the smoothing coil is wound on a second side leg among the side legs, and
a magnetic path common to the primary-side coil, the secondary-side coil, and the smoothing coil is formed on the center leg.

2. A power conversion device comprising:
a core forming a magnetic circuit;
a primary-side coil wound on the core;
a secondary-side coil magnetically coupled to the primary-side coil and wound on the core; and
a smoothing coil electrically connected to the secondary-side coil and wound on the core, wherein
the core has
a first core,
a second core opposed to the first core and disposed to be spaced from the first core,
a center leg which makes connection between a center portion of the first core and a center portion of the second core opposed to each other, and
a plurality of side legs which are away from the center leg and each of which makes connection between an end portion of the first core and an end portion of the second core opposed to each other,
the primary-side coil and the secondary-side coil are wound on a first side leg among the side legs,
the smoothing coil is wound on the center leg, and
a magnetic path common to the primary-side coil, the secondary-side coil, and the smoothing coil is formed on a second side leg among the side legs.

3. The power conversion device according to claim 1, wherein each of the primary-side coil, the secondary-side coil, and the smoothing coil is formed in a shape of a plate curved on a plane.

4. The power conversion device according to claim 2, wherein each of the primary-side coil, the secondary-side coil, and the smoothing coil is formed in a shape of a plate curved on a plane.

5. The power conversion device according to claim 1, further comprising a power conversion circuit which has a plurality of semiconductor switching elements and which performs conversion between DC power and AC power, wherein
the primary-side coil is electrically connected to an output side of the power conversion circuit, and
the power conversion circuit is a circuit employing a hard-switching method in which ON/OFF duty ratios of the plurality of semiconductor switching elements are changed to adjust output power.

6. The power conversion device according to claim 2, further comprising a power conversion circuit which has a plurality of semiconductor switching elements and which performs conversion between DC power and AC power, wherein
the primary-side coil is electrically connected to an output side of the power conversion circuit, and
the power conversion circuit is a circuit employing a hard-switching method in which ON/OFF duty ratios of the plurality of semiconductor switching elements are changed to adjust output power.

7. The power conversion device according to claim 1, wherein the center leg has no gap portion across which portions of the center leg are spaced from each other.

8. The power conversion device according to claim 2, wherein the second side leg has no gap portion across which portions of the second side leg are spaced from each other.

9. The power conversion device according to claim 1, wherein a cross-sectional area of the center leg is smaller than a sum of cross-sectional areas of the plurality of side legs.

10. The power conversion device according to claim 2, wherein a cross-sectional area of the second side leg is smaller than a sum of cross-sectional areas of the center leg and the plurality of side legs excluding the second side leg.

11. The power conversion device according to claim 1, wherein
the center leg is disposed to be spaced from each of the primary-side coil, the secondary-side coil, and the smoothing coil which are disposed to be adjacent to the center leg, and
side surfaces of the center leg have shapes that match shapes of respective side surfaces of the primary-side coil, the secondary-side coil, and the smoothing coil which are opposed to the side surfaces of the center leg.

12. The power conversion device according to claim 2, wherein
the second side leg is disposed to be spaced from the smoothing coil which is disposed to be adjacent to the second side leg, and
a side surface of the second side leg has a shape that matches a shape of a side surface of the smoothing coil which is opposed to the side surface of the second side leg.

13. The power conversion device according to claim 1, wherein a thickness of one or both of portions, of the first core and the second core, with which a magnetic flux of the smoothing coil interlinks is larger than a thickness of each of the first core and the second core with which magnetic fluxes of the primary-side coil and the secondary-side coil interlink.

14. The power conversion device according to claim 2, wherein a thickness of one or both of portions, of the first core and the second core, with which a magnetic flux of the smoothing coil interlinks is larger than a thickness of each of the first core and the second core with which magnetic fluxes of the primary-side coil and the secondary-side coil interlink.

15. The power conversion device according to claim 1, wherein the core is made of ferrite.

16. The power conversion device according to claim 2, wherein the core is made of ferrite.

17. The power conversion device according to claim 1, further comprising a rectification circuit which has a plurality of rectifier elements and which is electrically connected to the secondary-side coil, wherein
anode terminals of the plurality of respective rectifier elements are grounded.

18. The power conversion device according to claim 2, further comprising a rectification circuit which has a plurality of rectifier elements and which is electrically connected to the secondary-side coil, wherein
anode terminals of the plurality of respective rectifier elements are grounded.

19. The power conversion device according to claim 17, wherein the secondary-side coil and the smoothing coil are formed as an integrated coil member in which the secondary-side coil and the smoothing coil have been arranged side-by-side and have been electrically and mechanically coupled together by an integration portion.

20. The power conversion device according to claim 18, wherein the secondary-side coil and the smoothing coil are formed as an integrated coil member in which the secondary-side coil and the smoothing coil have been arranged side-by-side and have been electrically and mechanically coupled together by an integration portion.

21. The power conversion device according to claim 1, wherein the number of turns of the secondary-side coil is smaller than the number of turns of the primary-side coil.

22. The power conversion device according to claim 2, wherein the number of turns of the secondary-side coil is smaller than the number of turns of the primary-side coil.

23. The power conversion device according to claim 1, wherein
any leg, among the center leg and the plurality of side legs, on which a corresponding coil among the primary-side coil, the secondary-side coil, and the smoothing coil is wound and on which no magnetic path common to the primary-side coil, the secondary-side coil, and the smoothing coil is formed has a gap portion across which portions of the leg are spaced from each other, and
a spacer member is inserted into the gap portion.

24. The power conversion device according to claim 2, wherein
any leg, among the center leg and the plurality of side legs, on which a corresponding coil among the primary-side coil, the secondary-side coil, and the smoothing coil is wound and on which no magnetic path common to the primary-side coil, the secondary-side coil, and the smoothing coil is formed has a gap portion across which portions of the leg are spaced from each other, and
a spacer member is inserted into the gap portion.

25. The power conversion device according to claim 1, further comprising a cooler having a recess portion, wherein
a portion, of the second core, that is on an opposite side to the first core is thermally connected to a bottom of the recess portion, and
the primary-side coil or the secondary-side coil, and the smoothing coil, are thermally connected to a portion, of the cooler, that encloses an opening of the recess portion.

26. The power conversion device according to claim 2, further comprising a cooler having a recess portion, wherein
a portion, of the second core, that is on an opposite side to the first core is thermally connected to a bottom of the recess portion, and
the primary-side coil or the secondary-side coil, and the smoothing coil, are thermally connected to a portion, of the cooler, that encloses an opening of the recess portion.

27. The power conversion device according to claim 1, wherein
the plurality of side legs further include a third side leg and a fourth side leg,
the first side leg, the second side leg, the third side leg, and the fourth side leg are arranged away from the center leg so as to enclose the center leg,
the primary-side coil and the secondary-side coil are wound on the third side leg, and
the smoothing coil is wound on the fourth side leg.
